(19) United States
(12) Patent Application Publication
(10) Pub. No.: US 2012/0037504 A1
(43) Pub. Date: Feb. 16, 2012

(54) Multiply Divided Anode Wall Type Plasma Generating Apparatus and Plasma Processing Apparatus

(75) Inventors: Yuichi Shiina, Tokyo (JP); Iwao Watanabe, Tokyo (JP)

(73) Assignee: FERROTEC CORPORATION, Tokyo (JP)

(21) Appl. No.: 13/265,308

(22) PCT Filed: May 6, 2010
(86) PCT No.: PCT/JP2010/057770

§ 371 Date: Oct. 19, 2011

(30) Foreign Application Priority Data
Jul. 1, 2009 (JP) 2009-157158

(51) Int. Cl. C23C 14/32; B01J 19/08

(52) U.S. Cl. 204/298.41; 422/186.21

(57) ABSTRACT

An object of the present invention is to provide a multiply divided anode wall type plasma generation apparatus, wherein a short circuit between the cathode and the anode is not caused even if deposited matter adhering and depositing on the inner wall of the anode by diffusion plasma detach and fall. Also, an object is to provide a plasma processing apparatus using the same.

When the plasma (P) generated between the cathode (2) and the anode (3) is ejected forward from the cathode (2) and diffuses, the diffusing material (41) recrystalizes, adheres, and deposits on the inner wall of an electrode cylindrical body, and detaches and falls as a carbon flake (40). The inner wall of the electrode cylindrical body is multiply divided in the shape of a matrix by means of longitudinal and lateral grooves (37, 38). Even if the diffusing plasma adheres and deposits on the anode (3), the size of the deposited matter is reduced by the deposited matter separation effect by a large number of protruding portions (35), and no large or elongated deposited matter is produced. Carbon flakes (40) detach and fall as minute pieces from the protruding portions (39) which are of small size, none of the deposited matter that have detached and fallen extends over and bridges the cathode (2) and the anode (3), and thus a short circuit between both electrodes is prevented.

### FIELD OF THE INVENTION

The present invention concerns a plasma generation apparatus in which the supply source of the plasma constituent is made to be the cathode, a cylinder-like anode is set up at the front or perimeter of said cathode, and plasma is generated from the surface of said cathode by doing a vacuum arc discharge between said cathode and said anode under a vacuum environment, and a plasma processing apparatus that does plasma treatment such as film formation by anode by means of the generated plasma from said plasma generation apparatus. To be specific, the present invention concerns a multiply divided anode wall type plasma generation apparatus, and a plasma processing apparatus that uses the former.

### BACKGROUND ART

Normally, it is known that by forming a thin film or injecting ions in plasma onto the surface of a solid material, the solid surface characteristics are improved. A film formed using plasma including metal ions and nonmetal ions strengthens the abrasion and corrosion resistances of a solid surface, and it is useful as a protective film, an optical thin film, and a transparent electroconductive film among others. In particular, as for carbon films using carbon plasma, the utility value is high as diamond like carbon films (so-called DLC films) comprising amorphous mixed crystals of diamond and graphite structures.

As a method for generating plasma including metal ions and nonmetal ions, there is a vacuum arc plasma method. Vacuum are plasma is formed by an arc discharge occurring between a cathode and an anode. The cathode material evaporates from an existing cathode spot of the cathode surface, and it is plasma formed by this vaporized cathode material. Also, when a reactive gas is introduced as the environmental gas, the reactive gas is ionized simultaneously. An inert gas (so-called noble gas) may be introduced together with said reactive gas, and said inert gas can also be introduced instead of said reactive gas. By means of such plasma, a surface treatment can be done by a thin film formation or an ion injection onto a solid surface.

Normally, in a vacuum arc discharge, at the same time as vacuum arc plasma constituent particles such as cathode material ions, electrons, and cathode material neutral atom groups (atoms and molecules) are ejected by a cathode spot, cathode material particles named droplets of size ranging from less than submicron to several hundred microns (0.01-1000 μm) are also ejected. When these droplets adhere to the surface of an object to be treated, the uniformity of a film formed on the surface of the object to be treated surface is lost, a defective thin film is produced, and the surface treatment result of the film formation is affected.

A plasma arc machining apparatus having a droplet collecting portion is disclosed in Japanese Patent Laid-Open No. 2002-8893 bulletin (Patent Document 1). FIG. 21 is an outlined schematic diagram of a conventional plasma processing apparatus concerning Patent Document 1. At plasma generating portion 200, an electric spark is caused between cathode 201 and trigger electrode 202, and plasma 204 is produced by generating a vacuum arc between cathode 201 and anode 203. Power supply 205 for generating an electric spark and a vacuum arc discharge is connected to plasma generating portion 200, and plasma stabilizing magnetic field generators 206, 207 for stabilizing plasma 204 are positioned. Plasma 204 is guided to plasma processing portion 208 from plasma generating portion 200, and object to be treated 209 placed in plasma processing portion 208 is surface-treated by plasma 204. Also, a reactive gas is introduced as necessary by gas introduction system 210 connected to plasma processing portion 208, and reactant gases and the plasma stream are exhausted by gas exhaust system 211.

Plasma 204 ejected from plasma generating portion 200 is bent to a T-shape toward a direction away from plasma generating portion 200 by the magnetic field, and is flowed into plasma processing portion 208. At the position facing plasma generating portion 200, droplet collecting portion 212 is positioned, where cathode material particles (droplets) 213 generated as a byproduct at cathode at the time of generation of plasma 204 are collected. Therefore, droplets 213 not under an influence of the magnetic field advances to droplet collecting portion 212 and are collected, thereby preventing an intrusion of droplets 213 into plasma processing portion 208.

[Patent Document 1] Japanese Patent Laid-Open No. 2002-8893 bulletin

### DISCLOSURE OF THE INVENTION

### Problems to be Solved by the Invention

The conventional plasma crafting apparatus uses anode 203 comprising a cylinder-shaped electrode cylindrical body 214 extending toward the front side of cathode 201.

FIG. 22 shows the inner wall surface of a conventional electrode cylindrical body 214. When anode 203 is made to be the whole of the tube inside wall, because a vacuum arc becomes hard to be generated between it and cathode 201, many ring-like protruding portions 216 are set up by engraving multiple circular grooves 215 in the inner wall of electrode cylindrical body 214, so that a vacuum arc is generated smoothly between it and cathode 201.

When the plasma generated between cathode 201 and electrode cylindrical body 214 of anode 203 is released further forward than cathode 201 and diffused, diffusing material 218, mainly carbon (C) particles among the vacuum arc plasma constituent particles, recrystallizes on the inner wall of electrode cylindrical body 214 mainly, to adhere and deposit. In particular, when the recrystallization proceeds on the surface of a protruding portion 216, the deposited matter detaches in a flake-like configuration, and falls toward the cathode 201 side. However, because protruding portions 216 have a ring-like configuration, a problem occurs as shown in FIG. 22, in that when carbon flake 220 deposited in an elongated shape detaches from circular arc part 219 of a protruding portion 216 and falls toward the side of cathode 201, one end of carbon flake 220 is caught at upper side 217 of cathode 201 in a bridging manner, the other end comes in contact with anode 203, and cathode 201 and anode 203 are short-circuited.

The object of the present invention, in the view of the above problem, is to provide a multiply divided anode wall type plasma generation apparatus that can prevent a short-circuit between cathode and anode by a detached deposited matter that had adhered and deposited on the anode inner wall from the diffusion plasma, and a plasma processing apparatus that uses this.

### Means to Solve the Problems

The present inventors, as a result of having studied intensively to solve the short-circuit problem that occurs through the detachment phenomenon of large carbon flakes from ringed protruding portions, have succeeded in a size reduction of carbon flakes by a multiple division of the anode inner wall, and have thus solved the problem.

The first form of the present invention is, in a plasma generation apparatus in which a supply source of a plasma constituent is made to be a cathode, a cylinder-shaped anode is installed at a front direction or a periphery of said cathode, a vacuum arc discharge is done between said cathode and said anode under a vacuum environment, and plasma is generated from said cathode surface, a plasma generation apparatus, characterized in that a large number of recesses and protrusions is built on a cylinder inner wall that comprises said anode, so that when a part of said plasma ejected from said cathode to a direction of said anode adheres and deposits to said recesses and protrusions, said deposited matter detaches from said anode as a minute fragment.

The second form of the present invention is the plasma generation apparatus of the first form, wherein the longest length of a protruding portion of said recesses and protrusions is made shorter than the width of a gap between said cylinder inner wall and an outer circumference of said cathode.

The third form of the present invention is the plasma generation apparatus of the first or second form, wherein a large number of said recesses and protrusions is formed from any one of lattice-like, diagonally crossing, and island-like patterns.

The fourth form of the present invention is the plasma generation apparatus of the first, second, or third form, wherein within said cylinder inner wall comprising said anode, the area near said cathode is made to be a formation area of said pattern for said recesses and protrusions, and an annular groove pattern, in which a multiple annular grooves are engraved in a front direction of said cathode, is formed on a remaining area of said cylinder inner wall.

The fifth form of the present invention is the plasma generation apparatus of any one of the first to fourth forms, wherein an annular recess position is formed at a periphery of said cathode, so that said minute piece detached from said anode is retained and collected in said annular recess position.

The sixth form of the present invention is the plasma generation apparatus of any one of the first to fifth forms, wherein a retention portion for said minute piece is installed beneath said cathode, and at the same time, an exposing portion that communicates with said retention portion is formed at a periphery of said cathode, so that said minute piece detached from said anode is retained and collected in said retention portion through said exposing portion.

The seventh form of the present invention is a plasma processing apparatus, characterized in that it includes the plasma generation apparatus concerning any one of the first to sixth forms, a plasma transport tube that transports said plasma generated by said plasma generating apparatus, and a plasma processing portion that processes an object to be treated by said plasma supplied from said plasma transport tube.

The eighth form of the present invention is the plasma processing apparatus of the seventh form, wherein a starting end side insulator is interposed between a plasma outlet in a cylindrical body of said anode and said plasma transport tube, a finishing end side insulator is interposed between said plasma transport tube and said plasma processing portion, and said plasma generating portion, said plasma transport tube, and said plasma processing portion are mutually separated electrically so that an electric influence from said plasma generating portion and said plasma processing portion on said plasma transport tube is blocked.

The ninth form of the present invention is the plasma processing apparatus of the seventh or eighth form, wherein said plasma transport tube comprises a plasma straightly advancing tube connected to said plasma generating portion, a first plasma advancing tube connected in a bent manner to said plasma straightly advancing tube, a second plasma advancing tube diagonally arranged and connected at a finishing end of said first plasma advancing tube in a bent manner with predetermined bending angle with respect to a tube axis of said first plasma advancing tube, a third plasma advancing tube connected in a bent manner to a finishing end of said second plasma advancing tube so that said plasma is exhausted from a plasma outlet, and total length L for said plasma to arrive from said target surface to said object to be treated is set to satisfy 900 mm≦L≦1350 mm.

The tenth form of the present invention is the plasma processing apparatus of the seventh, eighth, or ninth form, wherein said second plasma advancing tube is placed geometrically at a position off a straight line of sight from a plasma outlet of said third plasma advancing tube to a plasma outlet side of said first plasma advancing tube.

The eleventh form of the present invention is the plasma processing apparatus of the ninth or tenth form, wherein θ≧θ₀ is satisfied when an angle of elevation from a tube cross section top end of the plasma entrance port side of said third plasma advancing tube to a tube cross section bottom end of the plasma outlet side of said first plasma advancing tube is defined as θ, and an angle of elevation from a tube cross section bottom end of the plasma outlet side of said third plasma advancing tube to a tube cross section top end of the plasma outlet side of said second plasma advancing tube is defined as θ₀.

The twelfth form of the present invention is the plasma processing apparatus of any one of the eighth to eleventh forms, wherein a magnetic field generating means for plasma transportation that generates a magnetic field for plasma transportation is set up in each of said plasma straightly advancing tube, said first plasma advancing tube, said second plasma advancing tube, and said third plasma advancing tube, a deflection magnetic field generating means for deflecting said magnetic field for plasma transportation is attached in said first plasma advancing tube and/or said second plasma advancing tube, and a plasma stream is deflected toward a tube center side by a deflection magnetic field generated by said deflection magnetic field generating means.

### Effects of the Invention

According to the first form of the present invention, a large number of said recesses and protrusions are arranged in the cylinder inner wall forming said anode so that it is multiply divided, and by the deposited matter separation effect of the large number of said recesses and protrusions, even if the diffusion plasma adheres and deposits to said anode, a large or elongated deposited matter do not form, and said deposited matter detaches as a minute piece from said anode. Because of this, said deposited matter do not bridge across said cathode and said anode upon detaching, a generation of short circuit between two electrodes can be prevented, and it contributes to a stable operation and an improvement of the operation efficiency of the plasma generation apparatus.

The placement of the anode in the present invention can be carried out so that it is located forward of the cathode, or in a placement form in which it surrounds a part or the whole of the cathode. Also, the cylindrical body structure of the anode is not limited to a cylindrical form with a uniform inside diameter, but the present invention can be applied with a frusto-conical internal wall structure.

The deposited matter as a carbon flake grows in a way associated with the size of the protruding portion surface of said recesses and protrusions. Therefore, according to the second form of the present invention, because the longest length of the protruding portions of said recesses and protrusions is made shorter than the width of the gap between said cylinder inner wall and the outer circumference of said cathode, a deposited matter larger than said gap does not detach, and a generation of a short circuit between the cathode and the anode can be prevented without causing a bridge formation by said deposited matter.

According to the third form of the present invention, because the large number of said recesses and protrusions is formed from any one of lattice-like, diagonally crossing, and island-like patterns, a multiple division of the cylinder inner wall forming said anode can be realized, the size of said deposited matter is reduced by the deposited matter separation effect of each pattern, and a generation of short circuit between the cathode and the anode can be prevented without causing a bridge formation by said deposited matter.

As for the quantity of deposition by diffusion plasma, it shows a tendency to increase in the periphery of said cathode that is the source of supply of the plasma constituent. Therefore, according to the fourth form of the present invention, by paying attention to this deposition tendency, a size reduction of the deposited matter is realized, by making the area near said cathode, within said cylinder inner wall comprising said anode, to be a formation area of said pattern for said recesses and protrusions. Also, by forming an annular groove pattern, in which a multiple annular grooves are engraved in the front direction of said cathode, on the remaining area of said cylinder inner wall, an area of the anode protruding portions formed by said annular groove pattern is obtained, inducing the generation of a vacuum arc with high efficiency. Because of these, a generation of short circuit between the cathode and the anode is prevented, and at the same time, an improvement of the plasma generation efficiency can be done.

According to the fifth form of the present invention, because an annular recess position is formed at a periphery of said cathode so that said minute piece detached from said anode is retained and collected in said annular recess position, said minute piece fallen around said cathode periphery does not deposit and come into contact with said cathode, and a generation of short circuit between the cathode and the anode can be prevented beforehand reliably.

According to the sixth form of the present invention, a retention portion for said minute piece is installed beneath said cathode, and at the same time, an exposing portion that communicates with said retention portion is formed at a periphery of said cathode, so that said minute piece detached from said anode is retained and collected in said retention portion through said exposing portion. Because of this, said minute piece that have detached and fell in said cathode periphery does not deposit at all, and a generation of short circuit between the cathode and the anode can be prevented even more reliably.

According to the seventh form of the present invention, when the plasma generated by the plasma generation apparatus of any one of said first to sixth forms is transported through said plasma transport tube and supplied to said plasma processing portion so that a film formation processing, for example, is done, a stable operation of said plasma generation apparatus can be done without producing a short circuit between the cathode and the anode, and an improvement of the process efficiency of film formation can be carried out.

In plasma treatment, high purity plasma is used for doing film formation among others, and there is a need to carry out an improvement of the surface treatment precision. Among the factors that obstruct a generation of high purity plasma, there is one caused by droplets generated from the target (cathode) mixing with the plasma. Among this type of droplets, there exist electrically charged droplets bearing positive and/or negative charge (positive droplets and negative droplets) and neutral droplets that do not bear a charge.

A plasma processing apparatus concerning the present invention has a plasma generation apparatus comprising an anode on which a large number of said recesses and protrusions have been formed, and the operation efficiency can be improved by preventing a detachment of a large carbon flake without decreasing the plasma generation efficiency. Moreover, a high purification of the generated plasma can be realized by applying removal measures for neutral and electrically charged droplets using the eighth to twelfth forms.

According to the eighth form of the present invention, by interposing a starting end side insulator between said plasma generating portion and said plasma transport tube, and interposing a finishing end side insulator between said plasma transport tube and said plasma processing portion, a complete electrical independence is achieved by said plasma generating portion, said plasma transport tube, and said plasma processing portion. As a result, an electric influence from said plasma generating portion and said plasma processing portion toward the plasma transport tube is completely blocked, the plasma transport tube that is usually formed from a metal becomes constant in terms of the electric potential as a whole, and an electric potential difference does not exist in the plasma transport tube. Because there is no electric potential difference, an electrical force, based on electric potential difference, toward charged particles is not generated. Because electrically charged droplets are one type of charged particles, an electrical force does not act on electrically charged droplets in a plasma transport tube in a constant electric potential state, and therefore electrically charged droplets can be handled in the same manner as neutral droplets. Therefore, by means of the geometric removal method of neutral droplets described below, it becomes possible for electrically charged droplets to be removed together with neutral droplets while advancing through the plasma transport tube. Because of this, the plasma supplied from the plasma transport tube becomes a high purity plasma from which neutral droplets and electrically charged droplets have been removed by the neutral droplet removal structure, and by this high purity plasma, a high purity plasma treatment is made possible toward an object to be treated in the plasma processing portion.

According to the ninth form of the present invention, the plasma generating apparatus is offered in which said plasma transport tube is composed in a bent manner in three stages of a plasma straightly advancing tube connected to said plasma generating portion, a first plasma advancing tube connected in a bent manner to said plasma straightly advancing tube, a second plasma advancing tube diagonally arranged and connected at the finishing end of said first plasma advancing tube in a bent manner with a predetermined bending angle with respect to the tube axis of said first plasma advancing tube, and a third plasma advancing tube connected in a bent manner to the finishing end of said second plasma advancing tube so that the plasma is exhausted from a plasma outlet, and total length L from the target surface to the object to be treated is set to satisfy 900 mm≦L≦1350 mm. Furthermore in details, said length L is defined as the total length that is the sum of length L0 from the target surface to the outlet of the plasma straightly advancing tube, length L1 of the first plasma advancing tube, length L2 of the second plasma advancing tube, length L3 of the third plasma advancing tube, together with plasma effective distance L4 that is the distance for the plasma to reach from the plasma outlet of said third plasma advancing tube to the object to be treated. That is to say, L=L0+L1+L2+L3+L4, and the detail is shown in FIG. 7, As thus described, because it is set so that said total length L satisfies 900 mm≦L≦1350 mm, as shown in FIG. 20, the film formation rate can be improved by shortening the plasma transport distance of the plasma advancing path furthermore than the conventional T-type plasma advancing paths and curved plasma advancing paths. Moreover, not merely the straightly advancing pathway is shortened, but neutral droplets are removed highly efficiently by said geometric structure of three stages of bent pathway. Furthermore, as stated above, electrically charged droplets are also removed highly efficiently by said geometric structure, and high purity plasma that can realize an improvement of surface treatment precision of film formation among others can be generated.

Said second plasma advancing tube is inclined in said bending angle (angle of inclination), and droplets can be blocked when the angle of inclination is large, but the film formation rate to the surface of the object to be treated decreases because the plasma density decreases. On contrary, when the angle of inclination is small, droplets intrude the treatment chamber, but the film formation rate to the surface of the object to be treated does not decrease because the decrease in the plasma density is small. Therefore, said angle of inclination can be chosen appropriately from the relation between the film formation rate and the tolerance for droplets.

Said bent pathway of three stages in the present invention by said plasma straightly advancing tube, said first plasma advancing tube, said second plasma advancing tube, and said third plasma advancing tube is comprised by connecting each tube on a same plane, or comprised by positioning them in three dimension spatially.

According to the tenth form of the present invention, said second plasma advancing tube is placed geometrically at the position away from the straight line of sight from the plasma outlet of said third plasma advancing tube to the plasma outlet side of said first plasma advancing tube. Because the droplets led out from said first plasma advancing tube are not exhausted directly from the plasma outlet of said third plasma advancing tube, but instead they collide with the pathway inner wall and are adhered and removed in said bent pathway process of three stages, the droplets adhering to the object to be treated can be largely reduced, and a plasma treatment becomes possible by high purity plasma from which droplets have been removed highly efficiently.

The outlet of said third plasma advancing tube may be connected directly to the outer wall surface of the plasma processing portion, or it may be positioned by inserting deeply in the inside of said outer wall surface. Furthermore, while maintaining the positional relationship between the outlet of said third plasma advancing tube and said outer wall surface, a rectifying tube and/or a deflection/oscillation tube could be installed between the second plasma advancing tube and the third plasma advancing tube.

According to the eleventh form of the present invention, θ≧θ₀ is satisfied when the angle of elevation from the tube cross section top end of the plasma entrance port side of said third plasma advancing tube to the tube cross section bottom end of the plasma outlet side of said first plasma advancing tube is defined as θ, and the angle of elevation from the tube cross section bottom end of the plasma outlet side of said third plasma advancing tube to the tube cross section top end of the plasma outlet side of said second plasma advancing tube is defined as θ₀. Because of this, said second plasma advancing tube can be placed at the position off the straight line of sight from the plasma outlet of said third plasma advancing tube to the plasma outlet side of said first plasma advancing tube. Therefore, for example, in cases where said bent pathway of three stages is comprised by connecting on a same plane, a tube passage configuration can be realized in which droplets led out from said first plasma advancing tube are not directly exhausted by the plasma outlet of said third plasma advancing tube, and a plasma treatment using high purity plasma from which droplets have been removed highly efficiently becomes possible.

As explained above, needless to say, the outlet of said third plasma advancing tube may be connected directly to the outer wall surface of the plasma processing portion, or it may be positioned by inserting deeply in the inside of said outer wall surface. Also, needless to say, a rectifying tube and/or a deflection/oscillation tube could be installed between the second plasma advancing tube and the third plasma advancing tube.

According to the twelfth form of the present invention, the magnetic field generating means for plasma transportation that generates a magnetic field for plasma transportation is set up in each of said plasma straightly advancing tube, said first plasma advancing tube, said second plasma advancing tube, and said third plasma advancing tube, the deflection magnetic field generating means for deflecting said magnetic field for plasma transportation is attached in said first plasma advancing tube and/or said second plasma advancing tube, and the plasma stream is deflected toward the tube center side by the deflection magnetic field generated by said deflection magnetic field generating means. Because of this, the heterogeneity of said magnetic field for plasma transportation at the connecting section of said first plasma advancing tube and/or said second plasma advancing tube, that is to say, the trouble in which the additional magnetic field becomes strong at the inside of the bending portion due to the configuration of said magnetic field coil for magnetic field generation for plasma transportation, is deflected and adjusted by said deflection magnetic field, the plasma stream is guided to the tube passage center, the plasma density is held high, and a plasma treatment using high density, high purity plasma becomes possible.

### BRIEF DESCRIPTION OF THE DRAWINGS

FIG. 1 is a cross section outlined schematic diagram of a plasma processing apparatus in which plasma generation apparatus 1 of the present invention has been installed.

FIG. 2 is a cross-section schematic diagram of the surroundings of plasma generating portion 4 in plasma generation apparatus 1.

FIG. 3 is a longitudinal sectional diagram showing the electrode cylindrical body of anode 3 for use in plasma generation apparatus 1.

FIG. 4 is a longitudinal sectional diagram showing the details of the electrode cylindrical body of anode 3.

FIG. 5 is a pattern diagram showing pattern examples of multiple divisions on an electrode cylindrical body of the present invention.

FIG. 6 is a longitudinal sectional diagram showing a variation in which a part of an anode inner wall has been multiply divided.

FIG. 7 is an outlined schematic diagram of a plasma processing apparatus concerning the present embodiment.

FIG. 8 is an outlined schematic diagram of a plasma processing apparatus concerning a different embodiment of the present invention.

FIG. 9 is an outlined schematic diagram of a plasma processing apparatus concerning another different embodiment of the present invention.

FIG. 10 is a schematic diagram of a bias power supply for use in the present invention.

FIG. 11 is an outlined schematic diagram of a plasma processing apparatus concerning the fourth embodiment of the present invention.

FIG. 12 is a placement diagram showing a placement state of movable yoke 129 concerning the fourth embodiment.

FIG. 13 is a schematic diagram showing a rotating adjustment mechanism of movable yoke 129.

FIG. 14 is a schematic diagram showing slide and swing adjustment mechanisms of movable yoke 129.

FIG. 15 is a model schematic diagram of a magnetic field coil for magnetic field generation for plasma transportation concerning the fourth embodiment.

FIG. 16 is a partially enlarged cross-sectional diagram of inner circumferential tube 161 concerning the fourth embodiment.

FIG. 17 is a plane view of a movable aperture 170 concerning the fourth embodiment, and an installation state diagram of aperture 170.

FIG. 18 is an outlined schematic diagram of a plasma processing apparatus of the fifth embodiment,

FIG. 19 is an explanatory diagram of a magnetic field for scanning formed inside frustoconical tube (deflection/oscillation tube) 1108 concerning the fifth embodiment.

FIG. 20 is a relational diagram showing the relation of plasma transport distance with respect to the film formation rate.

FIG. 21 is an outlined schematic diagram of a conventional plasma processing apparatus.

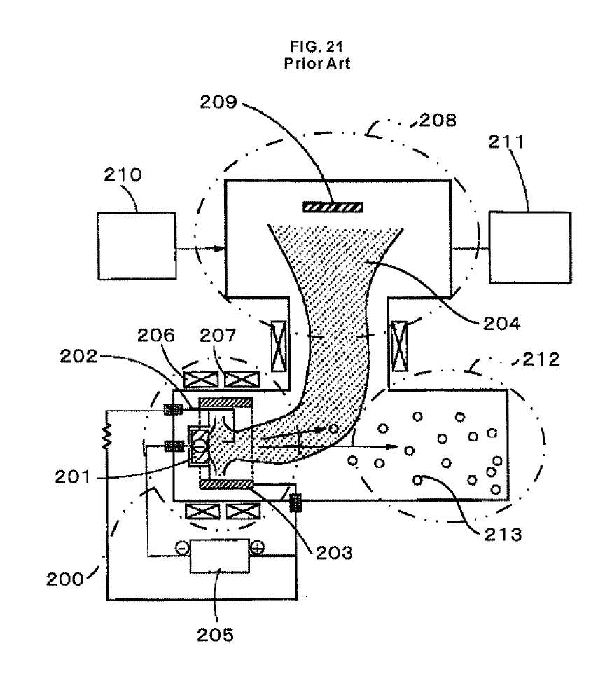

FIG. 22 is a longitudinal cross-section diagram of the inner wall surface of a conventional electrode cylindrical body 214.

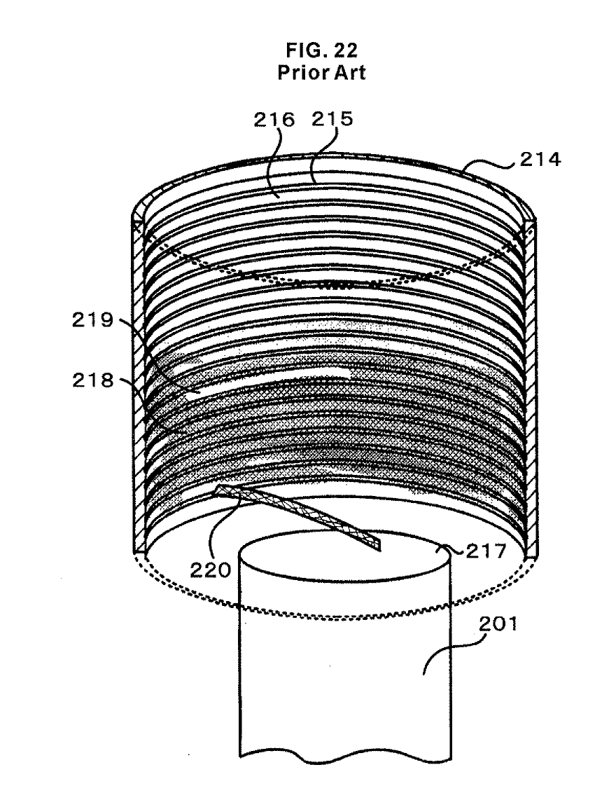

### DENOTATION OF REFERENCE NUMERALS

1 Plasma generation apparatus

2 Cathode

3 Anode

4 Plasma generating portion

5 Trigger electrode

6 Plasma advancing path

7 Bending portion

8 Bending magnetic field generator

9 Droplet advancing path

10 Droplet collecting portion

11 Baffle

12 Baffle

13 Radially enlarged tube

14 Magnetic field generator

15 Plasma processing portion

16 Object to be treated

17 Baffle

18 Magnetic field generator

19 Baffle

20 Magnetic field generator

21 Target coil

22 Filter coil

23 Radially reduced tube

24 Rotation shaft

25 Power supply

26 Electricity conduction line

27 Electricity conduction line

28 Anode inner wall

29 Outer wall

30 Insulation member

31 Insulation member

32 Electric discharge surface

33 Tube passage end

34 Gap

35 Protruding portion

36 Retention portion

37 Groove

38 Groove

39 Protruding portion of small fragment

40 Carbon flake

41 Diffusing material

42 Annular recess position

43 Protruding portion

44 Diagonal direction groove

45 Lateral groove

46 Hexagonal protruding portion

47 Honeycomb groove

48 Anode

49 Lattice-like recess-protrusion pattern

50 Annular groove pattern

101 Plasma processing portion

102 Plasma generating portion

103 Plasma straightly advancing tube

104 First plasma advancing tube

105 Second plasma advancing tube

106 Third plasma advancing tube

107 Plasma outlet

108 Arrow

108a X-direction oscillating magnetic field generator

108b Y-direction oscillating magnetic field generator

109 Arrow

110 Cathode

111 Trigger electrode

112 Anode

113 Arc power supply

114 Cathode protector

115 Plasma stabilizing magnetic field generator

116 Insulation plate

117 Magnetic field coil

118 Magnetic field coil

119 Magnetic field coil

121 Magnetic field coil

122 Deflection magnetic field generating means

123 Deflection magnetic field generating means

124 Deflection magnetic field generating means

125a Gas inflow port

125b Exhaust port

127 Magnetic pole

128 Magnetic pole

129 Movable yoke

130 Deflection magnetic field generating coil

131 Guiding body

132 Guiding groove

133 Pin

134 Fastening nut

135 Slide member

136 Spacer

137 Adjusting portion main body

138 Slide groove

139 Pin

140 Fastening nut

141 Droplet collecting plate (baffle)

142 Droplet collecting plate (baffle)

143 Droplet collecting plate (baffle)

144 Droplet collecting plate (baffle)

160 Droplet collecting plate (part of a baffle)

161 Inner circumferential tube

162 Opening

163 Bias power supply

170 Aperture

171 Opening

172 Stopper

173 Screw

174 Protrusion

175 Tube

176 Engagement recess

177 Arrow

200 Plasma generating portion

201 Cathode

202 Trigger electrode

203 Anode

204 Plasma

205 Power supply

206 Plasma stabilizing magnetic field generator

207 Plasma stabilizing magnetic field generator

208 Plasma processing portion

209 Object to be treated

210 Gas introduction system

211 Gas exhaust system

212 Droplet collecting portion

213 Cathode material particle

214 Electrode cylindrical body

215 Circular groove

216 Protruding portion

217 The upper side

218 Diffusing material

219 Circular arc part

220 Carbon flake

1109 Outlet tube

1100 Plasma straightly advancing tube

1101 First plasma advancing tube

1102 Second plasma advancing tube

1103 Third plasma advancing tube

1104 Connecting port

1105 Plasma outlet

1106 Plasma outlet

1107 Rectifying tube

1108 Frustoconical tube

1110 Plasma outlet

1111 Arrow

1112 Arrow

1113 Magnetic field coil for scanning

1114 Rectifying magnetic field coil

A Plasma generating portion

A1 Plasma generating portion container,

A2 Target exchange portion

B Plasma transport tube

B0 T-shaped transport tube

B2 Second transport tube

B23 Bending transport tube

B3 Third transport tube

C Plasma processing portion

C1 Installation position

C2 Target positon

C3 Processing portion container

CT Connection terminal

E Bias power supply

EA1 Bias power supply for container

EA2 Bias power supply for exchange portion container

EB Bias power supply for transport tube

EB01T Bias power supply for transport tube

EB2 Bias power supply for second transport tube

EB23 Bias power supply for bending transport tube

EB3 Bias power supply for third transport tube

EC Bias power supply for processing portion

EW Bias power supply for object to be treated

FT Floating terminal

GND Ground

GNDT Grounding terminal

IFA Finishing end side insulator

II1 The first middle insulator

ISA Starting end side insulator

IA Inter-container insulator

II2 The second middle insulator

NVT Variable negative electric potential terminal

P0 Plasma straightly advancing tube

P1 First plasma advancing tube

P2 Second plasma advancing tube

P3 Third plasma advancing tube

P4 Radially enlarged tube

PVT Variable positive electric potential terminal

S1 Plasma outlet

S2 Plasma entrance port

S3 Plasma outlet

VT Variable terminal

W Work

### BEST MODE FOR CARRYING OUT THE INVENTION

In the following, a multiply divided anode wall type plasma generation apparatus and plasma processing apparatus concerning an embodiment of the present invention is explained in detail, based on the attached figures.

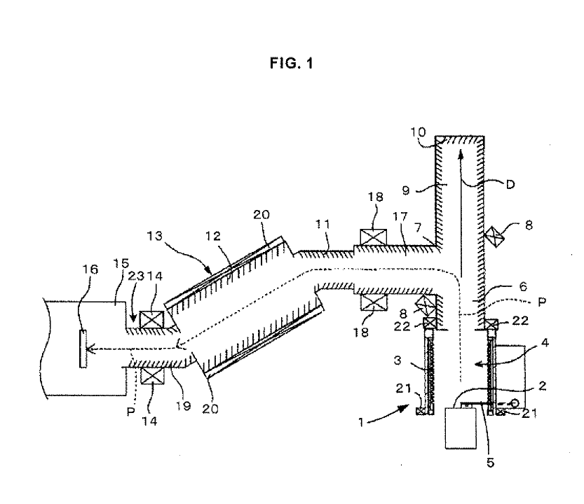

FIG. 1 is a cross section outlined schematic diagram of a plasma processing apparatus in which plasma generation apparatus 1 of the present invention has been installed. In plasma generating portion 4, a supply source of the plasma constituent material is made to be cathode 2 (a target), and cylinder-like anode 3 is arranged at the front side of cathode 2. Trigger electrode 5 is installed so that it is free to rotate, whereby it can approach toward and retreat from cathode 2. Anode 3 comprises an electrode cylindrical body in which the cylinder inner wall is made to have a multiply divided configuration. Plasma P is generated by causing an electric spark between cathode 2 and trigger electrode 5 under a vacuum environment, and generating a vacuum arc between cathode 2 and anode 3. By the vacuum arc discharge in plasma generating portion 4, vacuum arc plasma constituent particles such as target material ions, electrons, and cathode material neutral particles (atoms and molecules) are ejected, and at the same time, cathode material particles (subsequently referred to as “droplets D”) with size from less than submicron up to several hundred microns (0.01-1000 μm) are also ejected. The generated plasma P advances within plasma advancing path 6, and it advances to the second advancing path by means of a magnetic field formed by bending magnetic field generators 8, 8 in bending portion 7. At that instance, because droplets D are neutral electrically and therefore do not become influenced by a magnetic field, they advance straightly through droplet advancing path 9, and are collected at droplet collecting portion 10. A straightly advancing tube passage connecting with the second advancing path is installed in bending portion 7, and in the inner wall of each advancing path of plasma P in droplet advancing path 9 among others, baffles 11, 12 and 17 are installed, on which droplets D collide and adhere. As well, magnetic field generator 18 generating a plasma advancing magnetic field is set up in said straightly advancing tube passage.

The second advancing path comprises radially enlarged tube 13 in which multiple baffles 12 have been installed in the inner wall, and magnetic field generator 20 that generates a plasma advancing magnetic field is set up in radially enlarged tube 13. When plasma P advances through radially enlarged tube 13, the remaining droplets D collide with and adhere to said baffle 12, and thus droplets D are removed furthermore. Radially enlarged tube 13 is inclinedly arranged with respect to said straightly advancing tube passage. The finishing end of radially enlarged tube 13 is connected to plasma processing portion 15 through radially reduced tube 23. Plasma P from which droplets D have been removed is supplied to plasma processing portion 15 by the magnetic field of magnetic field generator 14, 14, and it can plasma-treat object to be treated 16. Baffle 19 is also set up in radially reduced tube 23.

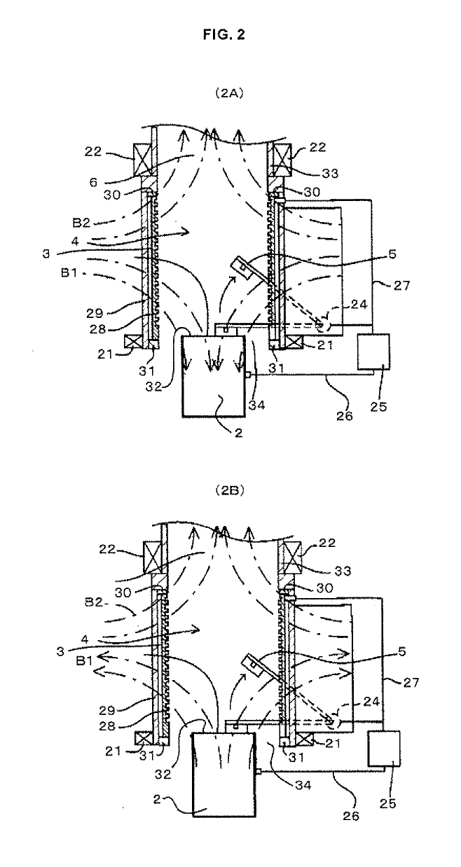

FIG. 2 is a cross-section schematic diagram of the surroundings of plasma generating portion 4. As shown in (2A) of the same figure, trigger electrode 5 comprises a striker that is axle-supported so that it is free to swing with rotation shaft 24 as the axis. By power supply 25, an electrical voltage is applied between anode inner wall 28/trigger electrode 5 of the striker and the target of cathode 2 through electricity conduction lines 26, 27. Plasma generating portion outer wall 29 does not come in contact with anode inner wall 28 because of insulation members 30, 31 mounted at the top and bottom ends of outer wall 29, and thus electrical neutrality is maintained. Tube passage end 33 of plasma advancing path 6 is connected to the plasma outlet side of plasma generating portion outer wall 29. The electrode cylindrical body of anode 3 is kept open in the cathode 2 side, and gap 34 is formed. Insulation member 30 corresponds to starting end side insulator IS that is explained below.

By separating the striker in the contact position as shown in solid line toward the separation direction, a vacuum arc discharge is induced between electric discharge surface 32 of cathode 2 and anode inner wall 28. The striker swings after receiving a rotational drive force from a rotational drive source (not shown). When the striker in the separated position is put into contact with electric discharge surface 32, the torque reaction force of the striker that has come in contact by the rotational drive source is detected, and the contact condition is confirmed. Furthermore, filter coil 22 is arranged at the plasma outlet side of plasma generating portion 4, and plasma advancing magnetic field 132 is formed. Stabilizing magnetic field B1 generated by target coil 21 is formed in reversed-phase (cusp) in comparison with plasma advancing magnetic field 132, so that a generation of stable plasma becomes possible. As shown in (2B) of FIG. 2, it is known that when stabilizing magnetic field B1 generated by target coil 21 is in-phase (mirror), the stability of the arc spot decreases, but the generation efficiency of plasma improves.

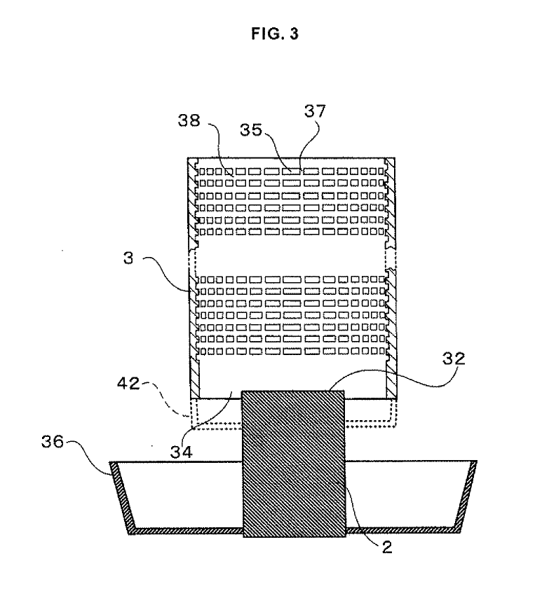

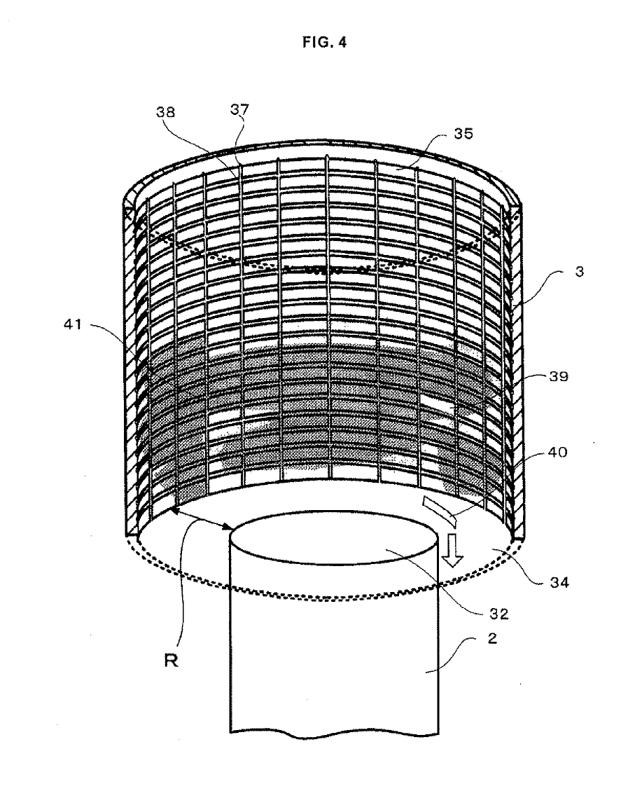

FIG. 3 is a longitudinal sectional diagram showing the electrode cylindrical body of anode 3. FIG. 4 is a longitudinal sectional diagram showing the details of said electrode cylindrical body.

In the inner wall of electrode cylindrical body of anode 3, recesses and protrusions are engraved in shape of a matrix by longitudinal and lateral grooves 37, 38, and thus many protruding portions 35 are formed. Protruding portions 35 have a thin rectangular box-like configuration that is curved. Beneath gap 34 set up at the lower part of the electrode cylindrical body, retention portion 36 larger that the diameter of the cylinder is placed for collecting carbon flakes.

As shown in FIG. 4, when plasma P generated between cathode 2 and anode 3 is ejected further forward than cathode 2 and diffused, diffusing material 41 recrystallizes on the electrode cylindrical body inner wall, adheres and deposits, and it detaches as carbon flake 40. In the present embodiment, because the electrode cylindrical body inner wall is multiply divided in shape of a matrix by means of longitudinal and lateral grooves 37, 38, even if the diffusion plasma adheres and deposits on anode 3, the size of the deposited matter is reduced by the deposited matter separation effect of the large number of protruding portions 35, and a large or long deposited matter is not produced at all. Therefore, for example, because only a minute piece of carbon flake 40 detaches from a small protruding portion 39, bridging of a detached deposited matter across cathode 2 and anode 3 does not occur, and a generation of short circuit between both electrodes can be prevented, contributing to a stable operation and an improvement of the operation efficiency of the plasma generation apparatus. The minute carbon flake 40 falls from gap 34 at the perimeter of cathode 2 toward beneath the arrow, and is collected in retention portion 36.

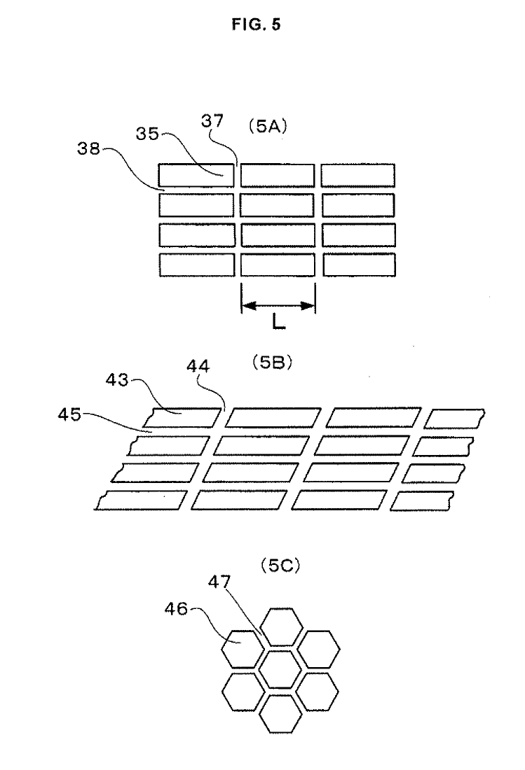

FIG. 5 shows pattern examples of multiple divisions on an electrode cylindrical body. (5A) of said figure is the lattice like matrix pattern used for the present embodiment. Carbon flakes grow according to the surface size of the protruding portions, and to increase the deposited matter separation effect, it is desirable that protruding portions 35 are as small as possible. Because the effective electrode surface area decreases if the multiple divisions are done excessively, it is sufficient to make the longest length L of protruding portions 35 at least shorter than width R of the gap between the cylinder inner wall and the cathode outer circumference (cf. FIG. 4). Even if a carbon flake corresponding to said length is detached, it can reliably be dropped below the exposing portion of gap 34, so that it can be collected.

A multiply divided pattern in the anode electrode cylindrical body is not limited to a lattice-like matrix pattern. For example, it can be a diagonally crossing pattern shown in (5B) of FIG. 5, or an island-like pattern shown in (5C) of the same figure. An example of a diagonally crossing pattern can be obtained by engraving diagonal direction grooves 44 against lateral grooves 45 in the cylinder inner wall, and forming protruding portions 43 having a rectangular box-like configuration that is curved. An example of an island-like pattern can be obtained by engraving honeycomb grooves 47 in the cylinder inner wall, and forming hexagonal protruding portions 46. Among the island-like patterns, water drop-like patterns with round-shaped protruding portions are included.

Because carbon flakes merely detach by use of a multiply divided anode concerning the present embodiment, annular recess position 42 surrounding cathode 2 in the lower part of gap 34 may be set up instead of retention portion 36, as shown by broken lines of FIG. 3, so that size-reduced carbon flakes may be collected. Although the frequency for flake collection increases in comparison with a large-scale retention portion 36, it is advantageous in that the surrounding of cathode 2 can be made compact.

Deposited mass on an anode inner wall by diffusion plasma tends to increase nearby cathode 2 that is the supply source of the plasma constituent material. Therefore, it is not always necessary to make multiple divisions on the entire surface of the anode inner wall, but it is sufficient to make multiple divisions in either the entirety or a part of the inner wall, according to the size of the anode area or the anode cylindrical body.

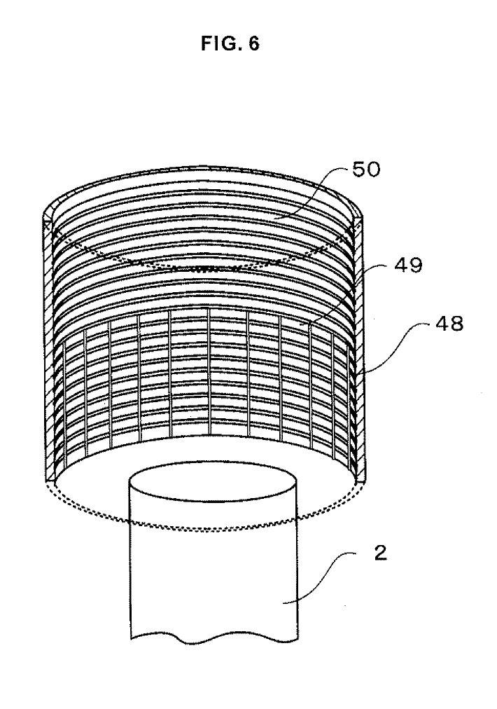

FIG. 6 shows a variation in which a part of an anode inner wall has been multiply divided. In this variation, within the inner wall of the electrode cylindrical body of anode 48, the half area near cathode 2 is made into a formation area of a lattice-like recess-protrusion pattern 49 shown above, and in the remaining half of the cylinder inner wall, annular groove pattern 50 is formed, in which multiple annular grooves are engraved in the forward direction of cathode 2. Therefore, a size reduction of deposited matter can be realized by recess-protrusion pattern 49 in the half area near cathode 2, and in the remaining cylinder inner wall, a large surface area is maintained for the anode protruding portions formed by annular groove patterns 50. Because of this, a generation of a vacuum arc can be induced highly efficiently, a generation of short circuit between the cathode and the anode can be prevented, and at the same time, an improvement of the plasma generation efficiency can be done.

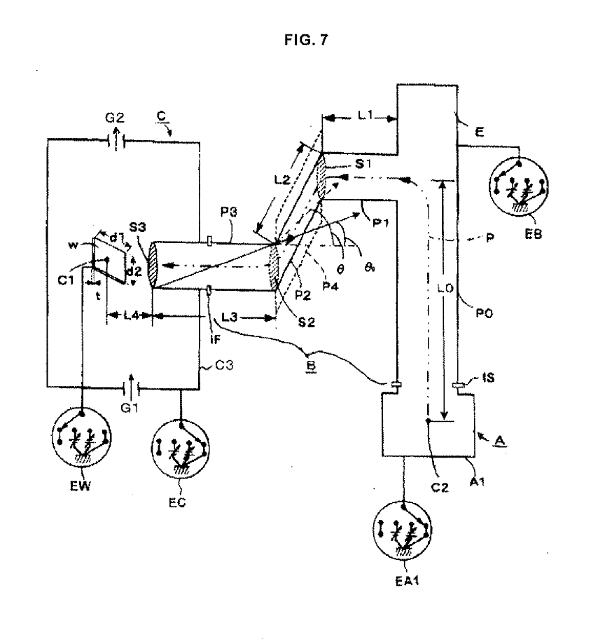

In a plasma processing apparatus concerning the present embodiment, plasma generation apparatus 1 comprising a multiply divided anode is provided, and an improvement of the operation efficiency is done by preventing a detachment of a large carbon flake without decreasing the plasma generation efficiency. Furthermore, it comprises a plasma high-purification configuration, in which neutral droplets and electrically charged droplets can be removed with higher efficiency. In the following, the plasma high-purification configuration in a plasma processing apparatus of the present embodiment is explained. In FIGS. 7-9, the explanation is done while focusing on the plasma transport pathway, and the configuration aside from that of the plasma transport pathway is illustrated in a simplified mode.

FIG. 7 shows an outlined scheme of the plasma transport pathway in a plasma processing apparatus of the present embodiment. In the plasma processing apparatus concerning the present embodiment, starting end side insulator IS is interposed between the plasma outlet in the cylindrical body of anode 3 and the plasma transport tube, finishing end side insulator IF is interposed between the plasma transport tube and plasma processing portion 15, and thus plasma generating portion 1, the plasma transport tube, and plasma processing portion 15 are mutually separated electrically so that an electric influence from plasma generating portion 1 and plasma processing portion 15 on the plasma transport tube is blocked.

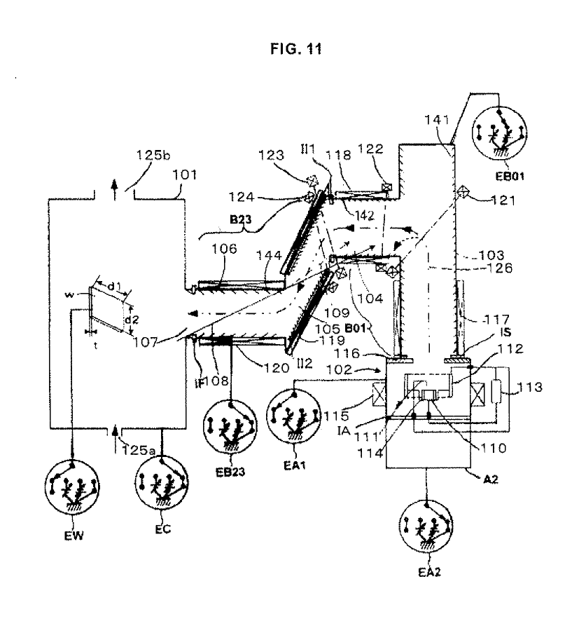

It is composed of plasma generating portion A that generates the plasma supplied to plasma processing portion C (a chamber), and plasma transport tube B. Plasma generating portion A corresponds to plasma generating portion 4. In plasma processing portion C, work (object to be treated by plasma) W is set up, a reactive gas is introduced as necessary by a gas introduction system connected into the chamber from gas inflow port G1, and reactant gas and plasma stream are exhausted from exhaust port G2 by a gas exhaust system. Plasma generating portion A has a cathode (target) that generates plasma by vacuum arc discharge under a vacuum environment. Plasma transport path B comprises a tube passage that mobilizes plasma, and plasma transport path B also has a structure of a droplet removing portion that removes droplets produced as a byproduct from the cathode by its geometrical structure. This plasma transport path B is also a plasma stream distribution tube passage, and comprises plasma straightly advancing tube P0 connected to plasma generating portion A, first plasma advancing tube P1 connected in a bent manner to plasma straightly advancing tube P0, second plasma advancing tube P2 inclinedly arranged and connected at the finishing end of first plasma advancing tube P1 in a predetermined bending angle with respect to the tube axis, and third plasma advancing tube P3 connected in a bent manner at the finishing end of second plasma advancing tube P2 so that plasma is exhausted from the plasma outlet. Second plasma advancing tube P2 corresponds to said second advancing path of FIG. 1 comprising radially enlarged tube 13. Outlet S3 of said third plasma advancing tube P3 is inserted deeply and extended inside the outer wall surface of said plasma processing portion C, but as shown in FIG. 11 described below, said outlet S3 may be directly connected to said outer wall surface through a flange (not shown). The connection type can be adjusted freely.

Plasma straightly advancing tube P0 adheres and removes droplets advancing straightly from plasma generating portion A by colliding them against finishing end section E opposite plasma generating portion A, or against the tube inner wall. The plasma advancing length from said target position C2 of plasma generating portion A to the outlet of plasma straightly advancing tube P0, that is to say, the connection point between plasma straightly advancing tube P0 and first plasma advancing tube P1, is defined as L0. First plasma advancing tube P1 communicates and connects toward the perpendicular direction at the side wall of the finishing end side of plasma straightly advancing tube P0. The plasma advancing length of first plasma advancing tube P1 is defined as L1. Second plasma advancing tube P2 is inclinedly arranged between first plasma advancing tube P1 and third plasma advancing tube P3, and its plasma advancing length is defined as L2. Third plasma advancing tube P3 is placed toward a parallel direction with respect to first plasma advancing tube P1, and its plasma advancing length is defined as L3. The plasma outlet of third plasma advancing tube P3 is extended inside the plasma processing portion C. The plasma effective distance in which the plasma exhausted from the plasma outlet of third plasma advancing tube P3 arrives at installation position C1 of the object to be treated in plasma processing portion C is defined as L4. A plasma advancing path formed in a bent manner in three stages is formed by plasma straightly advancing tube P0, first plasma advancing tube P1, second plasma advancing tube P2, and third plasma advancing tube P3.

Around the outer circumference of each plasma advancing tube, a magnetic field coil (not shown) for generating a magnetic field for plasma transportation is wound with a purpose to transport plasma stream along the tube passage. By magnetic field generating means for plasma transportation comprising of magnetic field coil, a magnetic field for plasma transportation is generated in the whole three stages of said bent pathway, and the plasma transport efficiency is improved. Also, a baffle (not shown) for droplet removal is set up in the tube inner wall.

In the plasma advancing path concerning the above configuration, total length (plasma transport distance) L(=L0+L1+L2+L3+L4), which is the sum of plasma advancing lengths L0-L3 respectively of the interval from the target surface to the outlet of plasma straightly advancing tube P0, first plasma advancing tube P1, second plasma advancing tube P2, and third plasma advancing tube P3, together with plasma effective distance L4, is set to satisfy 900 mm≦L≦1350 mm.

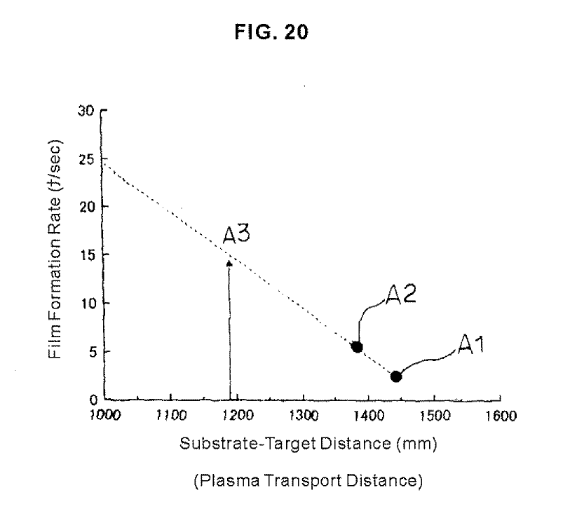

FIG. 20 is a relational diagram showing the relation of the plasma transport distance with respect to the film formation rate. In the present embodiment, L is set to be 1190 mm, as shown in A3 of FIG. 20. Under setting of this plasma transport distance, when a plasma exposure was done on one piece of substrate in the same manner as the above verification experiments for A1 and A2, and a film formation of thickness of 3 nm was carried out, a film formation rate of about 1.5 nm/sec was obtained.

According to the present embodiment, the plasma transport distance in the above plasma advancing path is shortened further than a conventional T-shaped plasma advancing path (A1 of FIG. 20) and a curved plasma advancing path (A2 of FIG. 20), and thus the film formation rate can be improved. Moreover, not only the straight advancing path is shortened, but also droplets are removed with higher efficiency by said pathway bending in three stages, and thus high purity plasma that can realize an improvement of the surface treatment precision of film formation and such can be generated. That is to say, the plasma transport distance is shortened in comparison to the cases in which a plasma advancing path bent in a T-shape (A1) and a bent plasma advancing path (A2) were used, and moreover, a high film formation rate (about 1.5 nm/sec) can be obtained as a good film formation condition for use in semiconductor substrates.

In the present embodiment, the plasma advancing path consists of said bent pathway of three stages, and furthermore, by the tube passage placement shown in FIG. 7 or 11, an extremely good droplets removal effect is obtained. By this droplet removal effect, when plasma was irradiated for 4 seconds against a substrate (work W) with a size of 2.5 in (inch) width d1, 2.5 in (inch) length D2, and an arbitrary thickness t, the deposited number of droplets became less than 10-100.

Second plasma advancing tube P2 is placed geometrically at a position off the straight line of sight from plasma outlet S3 of third plasma advancing tube P3 to the plasma outlet S1 side of first plasma advancing tube P1. That is to say, when the angle of elevation from the tube cross section top end of the plasma entrance port S2 side of third plasma advancing tube P3 to the tube cross section bottom end of the plasma outlet S1 side of first plasma advancing tube P1 is defined as θ, and when the angle of elevation from the tube cross section bottom end of the plasma outlet S3 side of third plasma advancing tube P3 to the tube cross section top end of the plasma outlet S2 side of second plasma advancing tube P2 is defined as θ₀, θ≧θ₀ is satisfied.

By the above geometric tube passage placement, straightly advancing droplets led out from first plasma advancing tube P1 are prevented from directly intruding third plasma advancing tube P3, so that they cannot be exhausted from plasma outlet S3 of third plasma advancing tube P3. Therefore, it becomes possible to adhere and remove the droplets by collision at the pathway inner wall during said bent pathway process of three stages, the adhesion mass of the droplets on the object to be treated can be reduced greatly as described above, and a plasma treatment by high purity plasma from which droplets have been removed with high efficiency can be done.

In the present embodiment, said bent pathway of three stages is connected and composed on a same plane, but even when the tube pathway is composed in a spatially bent manner in three stages, by the same geometric arrangement as above, a tube pathway arrangement can be realized in which the straightly advancing plasma is not exhausted directly from the plasma outlet of the third plasma advancing tube.

As shown by the broken lines, second plasma advancing tube P2 may be built as radially enlarged tube P4 whose inner diameter is greater than first plasma advancing tube P1 and third plasma advancing tube P3. That is to say, second plasma advancing tube P2 is set up as radially enlarged tube P4, first plasma advancing tube P1 is set up as an introduction side radially reduced tube connected to the plasma introduction side starting end of radially enlarged tube P4, and third plasma advancing tube P3 is set up as a discharge side radially reduced tube connected to the plasma discharge side finishing end of radially enlarged tube P4. If radially enlarged tube P4 is positioned midway, the plasma stream introduced from the introduction side radially reduced tube into the radially enlarged tube is diffused by the diameter-increasing effect of the plasma advancing path by radially enlarged tube P4. By the diffusion of this plasma stream, the droplets mixed with the plasma diffuse inside the radially enlarged tube P4, and are collided with, adhered to, and collected at the inner side wall of radially enlarged tube P4. Also, when the plasma stream in radially enlarged tube P4 is exhausted, the droplets scattered in the radially enlarged tube inner wall surface side are collided with, adhere to, and collected by the step portion by the diameter-narrowing effect from radially enlarged tube P4 to discharge side radially reduced tube, and thereby the droplets are not rejoined with the plasma stream, and a re-mixture of droplets can be prevented. Therefore, the droplets can be adhered to the internal side wall of radially enlarged tube P4, and thus can be collected sufficiently. Because of this, the droplets can be removed efficiently inside the tube path of first plasma advancing tube P1, second plasma advancing tube P2, and third plasma advancing tube P3. Also, when the central axes of radially enlarged tube P4 and the introduction side radially reduced tube and/or the discharge side radially reduced tube are set off instead of being lined up, the droplets become easy to separate from the plasma stream, and the capture effect of droplets increases even more. Moreover, just by forming radially enlarged tube P4 in the plasma advancing path, a droplet removing portion can be constituted easily and cheaply.

Said bent structure in three stages and angle relation θ≧θ₀ are mainly for providing the geometric structure of plasma transport path B installed in order to remove droplets advancing straightly, such as neutral droplets. Because electrically charged droplets are influenced by the electric effect and magnetic action from the environment, they may deviate from straight advancement in an electromagnetic field because of the electric field and/or the magnetic field. Therefore, in order to remove the electrically charged droplets, it is necessary to equip with a mechanism to intentionally remove in particular the electric potential difference from the plasma transport path. Because a magnetic field for plasma transport is necessary by all means, it is difficult to remove a magnetic field in a plasma device. Because the electric force towards the electrically charged droplets can be erased when the electric potential difference is removed, in this case the electrically charged droplets have a property of advancing straightly in the same manner as neutral droplets, and it becomes possible to remove the electrically charged droplets too by the previously described geometrical structure.

The plasma processing apparatus of present embodiment has a structure for removal of electrically charged droplets. Plasma generating portion A and plasma transport tube B are mutually insulated electrically by starting end side insulator IS, and moreover, plasma transport tube B and plasma processing portion C are mutually insulated electrically by finishing end side insulator IF. As a result, plasma transport tube B does not receive an electric influence from plasma generating portion A and plasma processing portion C at all, and plasma transport tube B is set so that the electric potential is constant throughout. As mentioned above, plasma transport tube B comprises plasma straightly advancing tube P0, first plasma advancing tube P1, second plasma advancing tube P2, and third plasma advancing tube P3, and because the electric potential becomes constant throughout the tube arrangement, no electric potential difference exists at all inside plasma transport tube B, and the electrically charged droplets do not receive at all an electric force from an electric potential difference inside plasma transport tube B. Therefore, electrically charged droplets too are removed inside plasma transport tube by the previously described structures in three stages and the angle relation θ≧θ₀, in the same manner as neutral droplets.

Also, a bias power supply can be additionally installed in each component of present plasma processing apparatus. In FIG. 7, bias power supply EA1 for container is installed at plasma generating portion container A1, bias power supply EB for transport tube is provided near plasma transport tube B, bias power supply EC is provided at processing portion container C3 that is a housing of plasma processing portion C for processing portion, and bias power supply EW for portion for object to be treated is provided near work W.

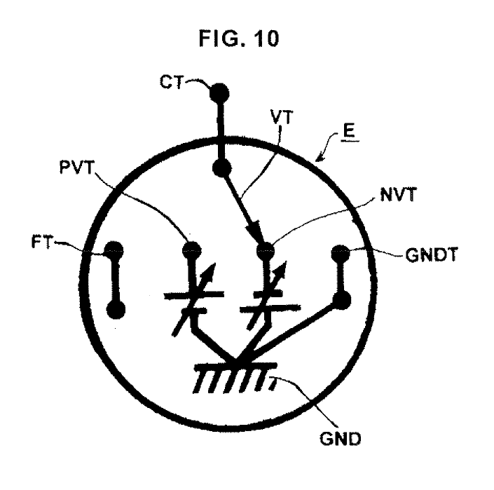

Each bias power supply EA1, EB, EC, and EW has a same structure, and this structure is explained by using FIG. 10. FIG. 10 is the structural diagram of a bias power supply used in the present invention. Connection terminal CT is a terminal connected to each component. Variable terminal VT attached to connection terminal CT can be varied in four stages. The receiving side terminal of four stages comprises floating terminal FT, variable positive voltage terminal PVT, variable negative voltage terminal NVT, and grounding terminal GNDT. When variable terminal VT is connected to floating terminal FT, floating terminal FT is in an electrically floating state, and it is not connected to any part. When variable terminal VT is connected to variable positive voltage terminal PVT, a positive electric potential with respect to GND (the ground side) is applied to the component parts in a manner that it can be varied in magnitude (0 to +50V). When variable terminal VT is connected to variable negative voltage terminal NVT, a negative electric potential with respect to GND (the ground side) is applied in a manner that it can be varied in magnitude (0 to −50V). When variable terminal VT is connected to grounding terminal GNDT, the component part is grounded.

FIG. 7 shows a suitable electric potential placement, plasma generating portion container A1 is set up at GND by said bias power supply EA1 for containers, plasma transport tube B is set in an electric floating state by bias power supply EB for transport tube, processing component container C3 is set up at GND by bias power supply EC for processing component, and work W is set in an electric floating state by bias power supply for portion for object to be treated EW. Because plasma generating portion container A1 is insulated from the arc power supply for plasma generation, a safety design is done on plasma generating portion container A1 grounded by GND, for safety even upon a contact by a worker. Because processing component container C3 too is grounded by GND, it is safe even if a worker comes in contact with it. Because plasma transport tube B is in an electric floating state, and the electric potential is constant as a whole, there is no electric potential difference within plasma transport tube B as described above, and electrically charged droplets too can be surely removed in the same manner as neutral droplets by the geometrical structure for droplets removal. Work W set to an electric floating state also has a constant electric potential as a whole, therefore the electric effect on the plasma is not unbalanced, and the plasma can be received evenly throughout the entire surface.

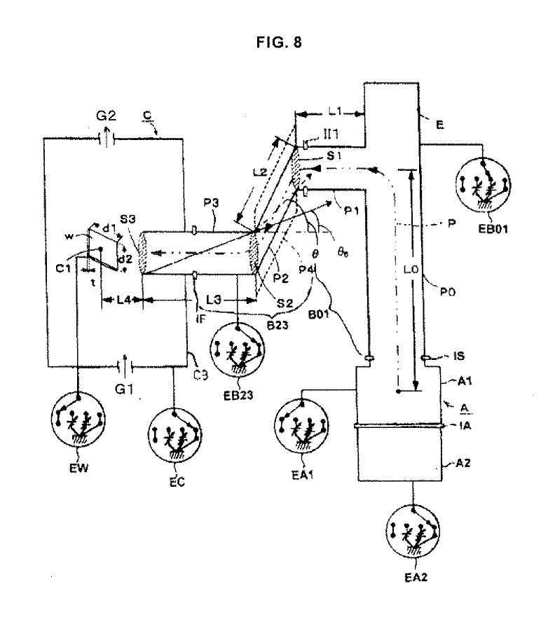

FIG. 8 is an outlined schematic diagram of a plasma processing apparatus concerning a different embodiment of the present invention. The first difference with the embodiment in FIG. 7 is that target exchange portion container A2 has been set up at the bottom of plasma generating portion container A1 through inter-container insulator IA, and bias power supply EA2 for exchange portion container has been attached at target exchange portion container A2. In target interchange portion container A2, a reserve target (not shown) is built in as a replacement when the target in plasma generating portion A has worn out, and at the same time, an exchange mechanism (not shown) is built in. The second difference is that plasma transport tube B is split into T-shaped transport tube B01 and bending transport tube B23 by first middle insulator II1, bias power supply EB 23 for bending transport tube is attached at bending transport tube B23, and bias power supply EB 01 for T-shaped transport tube is attached at T-shaped transport tube B01. Otherwise it is completely same as FIG. 7, and the working effect of the difference is described in particular as follows.

Bias power supply EA2 for exchange portion container is grounded at GND, and it is designed for safety even in a case of contact by a worker. Bias power supply EA1 for the container of plasma generating portion A is set to an electric floating state, so that the electric effect toward the plasma is erased, and a stable plasma generation is promoted. Bias power supply for T-shaped transport tube is connected to variable negative voltage terminal NVT of FIG. 10, and T-shaped transport tube B01 is dropped to a negative electric potential. It was found experimentally that the removal efficiency of electrically charged droplets increased when this negative electric potential was adjusted within a range of −5 to −10V. Bias power supply EB23 for bending transport tube is connected to GND. In this the second form, as the location of the bias power supply is varied from EA2→EA1→EB→EB 23, the electric potential of the tubing work varies from GND→floating state→(−5 to −10V)→GND, and it became clear from the current experimental examples that this change in the electrical potential is effective for removal of electrically charged droplets. The reason is not clear, but it can be thought that when the electric potential is varied to be GND→negative electric potential→GND, positive droplets are adsorbed electrically by the transport tube in the first GND→negative electric potential change, and negative droplets are adsorbed electrically by the transport tube in the next negative electric potential→GND change.

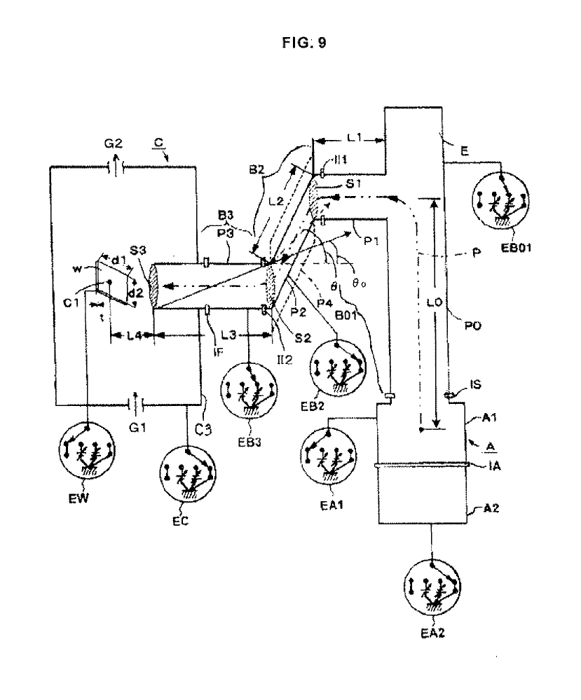

FIG. 9 is an outlined schematic diagram of a plasma processing apparatus concerning another different third embodiment of the present invention. The difference with FIG. 8 is that bending transport tube B23 has been split into second transport tube B2 and third transport tube B3 by second intermediate insulator II2. As a result, bias power supply EB2 for second transport tube has been attached to second transport tube B2, and bias power supply EB3 for third transport tube has been attached to third transport tube B3. Otherwise, it is completely same as FIG. 8, and the working effect of the difference is described in particular as follows.

In FIG. 9, bias power supply EB2 for second transport tube is grounded by GND, and bias power supply EB3 for third transport tube is connected to variable negative voltage terminal NVT of FIG. 10 so that it is set to a negative electric potential. It was obtained experimentally that it becomes favorable if the negative electric potential of bias power supply EB3 for third transport tube is adjusted within a range of 0 to −15V. In this third embodiment, as the location of the bias power supply varies from EA2→EA1→EB01→EB2→EB3, the electric potential of its tubing work varies from GND→floating state→(−5 to −10V)→GND→negative electric potential. It became clear from current experimental examples that this electric potential variation is effective for removal of electrically charged droplets. The reason is not clear, but it can be thought that when the electric potential changes from GND→negative electric potential→GND→negative electric potential, positive droplets are adsorbed electrically by the transport tube in the first GND→negative electric potential change, negative droplets are adsorbed electrically by the transport tube in the next negative electric potential→GND change, and furthermore, the remaining positive droplets are adsorbed electrically by the transport tube in the next GND→negative electric potential change.

As explained above, the variable positive electric potential of each bias power supply EW, EC, EB3, EB2, EA1, EA2, and EB01 can be adjusted within a range of 0 to +50V, and the variable negative electric potential is adjusted within a range of 0 to −50V. The electric potential of each bias power supply is varied and adjusted so that the droplet removal efficiency of the apparatus as whole is maximized within these electric potential ranges.

Next, an installation example of magnetic field coils that are suitable for a plasma processing apparatus in the present invention is explained, as well as an installation example of baffles (collecting plates) for droplet removal. FIG. 11 is an outlined schematic diagram of a plasma processing apparatus concerning the fourth embodiment of the present invention. An apparatus of FIG. 11 is the apparatus of FIG. 8 with installation at the outer tube circumference of a magnetic field coil generating a magnetic field for plasma transportation. Also, it shows a plasma processing apparatus in which baffles for droplet removal are set up in the tube inner wall. In this embodiment, the connection mode is adopted in which the outlet of the third plasma advancing tube is directly connected to the outer wall surface of plasma processing portion 1. In the same manner as FIG. 8, inter-container insulator IA, starting end side insulator IS, first middle insulator II1, and finishing end side insulator IF are placed, and they comprise the electric insulation of the apparatus as a whole. Also, the member reference numerals are shown as alphabetical characters in FIG. 8, but the member reference numerals are shown as numerical characters in FIG. 11. However, this is not a substantive difference. Also, an alphabetical reference numeral shows a same member in FIG. 8 as in FIG. 11, and because the configuration and the working effect are already described in FIG. 8, the explanation of the equivalent parts is omitted in FIG. 11, and therefore, the structural geometry of droplet removal is mainly explained below.

Plasma processing apparatus of FIG. 11 comprise plasma processing portion (chamber) 101 equipped with gas inflow port 125a and exhaust port 125b, a plasma processing apparatus comprising plasma generating portion 102 generating plasma to be supplied to plasma processing portion 101, together with plasma transport tubes. A plasma transport tube comprises a plasma distribution tube passage in which a droplet removing portion for removing droplets is positioned, just as in FIG. 8. In the following, because the structure of plasma transport tube B in itself constitutes a droplet removing portion, “droplet removing portion” signifies plasma transport tube B that has a droplet removal structure. The droplet removing portion of the present fourth embodiment comprises plasma straightly advancing tube 103 connected to plasma generating portion 102, first plasma advancing tube 104 connected in a bent manner to plasma straightly advancing tube 103, second plasma advancing tube 105 diagonally arranged and connected at the end of first plasma advancing tube 104 in a predetermined bending angle against its tube axis, and third plasma advancing tube 106 connected in a bent matter at the finishing end of second plasma advancing tube 105 so that it exhausts plasma from plasma outlet 107.

The plasma transport tube comprising plasma straightly advancing tube 103, first plasma advancing tube 104, second plasma advancing tube 105, and third plasma advancing tube 106 is formed in a bent manner in three stages, just like the plasma transport tube of FIG, 8. Plasma outlet 107 of third plasma advancing tube 106 is connected to plasma introduction port of plasma processing portion 101. Also, second plasma advancing tube 105 is placed geometrically at a position off the line of sight from plasma outlet 107 of third plasma advancing tube 106 to the plasma outlet side of first plasma advancing tube 104, in the same manner as FIG. 8. That is to say, when, as shown by arrow 109 depicted by a dashed line, the angle of elevation from the tube cross section bottom end of plasma outlet 107 side of third plasma advancing tube 106 to the tube cross section top end of the plasma outlet side of second plasma advancing tube 105 is defined as θ₀, angle of elevation (θ), as shown by arrow 109, from tube cross section top end of the plasma entrance port side of third plasma advancing tube 106 to the tube cross section bottom end of the plasma outlet side of first plasma advancing tube 104, satisfies θ≧θ₀. By the same geometric tube passage placement as FIG. 8, a direct intrusion of straightly advancing droplets led out from first plasma advancing tube 104 into third plasma advancing tube 106 is prevented, so that they do not get exhausted from plasma outlet 107 of third plasma advancing tube 106.

Plasma generating portion 102 comprises cathode (cathode) 110, trigger electrode 111, inner wall multiply divided anode (anode) 112, arc power supply 113, cathode protector 114, and plasma stabilizing magnetic field generator (an electromagnetic coil or a magnet) 115. Cathode 110 is the supply source of the plasma constituent, and its formation material is not limited particularly as long as it is a solid having electroconductivity. A simple metal, an alloy, a simple inorganic substance, an inorganic compound (metallic oxide/nitride) and such can be used individually or as a mixture of two or more substances. Cathode protector 114 electrically insulates parts other than evaporating cathode surface, and prevents a backward diffusion of plasma generated between cathode 110 and anode 112. The formation material of anode 112 is not limited particularly, as long as it does not evaporate at the plasma temperature, and it is a nonmagnetic material that is a solid having electroconductivity. Also the configuration of anode 112 is not limited particularly, as long as it does not obstruct an advancing of arc plasma as a whole. Furthermore, plasma stabilizing magnetic field generator 115 is placed around the circumference of plasma generating portion 102, and it stabilizes the plasma. When arc stabilization magnetic field generator 115 is placed so that the applied magnetic field on the plasma is in mutually reverse direction (cusp form), the plasma is stabilized further. Also, when arc stabilization magnetic field generator 115 is placed so that the applied magnetic field on the plasma is in mutually same direction (mirror form), the deposition rate by the plasma can be improved. Furthermore, plasma generating portion 102 and each plasma tube path are electrically insulated by plasma generating portion side insulation plate 116, and the construction is such that, even if a high voltage is applied to plasma generating portion 102, the portions at forward of plasma straightly advancing tube 103 is in an electrically floating state, so that plasma does not receive an electrical influence inside the plasma advancing path. Also, a processing component side insulation plate (finishing end side insulator IF) is placed between third plasma advancing tube 106 and plasma processing portion 101, the whole of the duct portion for plasma transportation from plasma straightly advancing tube 103 to third plasma advancing tube 106 is set to an electrically floating state, and constructed so that the transported plasma is not influenced by an external power supply (high voltage source and/or GND).

In plasma generating portion 102, an electric spark is triggered between cathode 110 and trigger electrode 111, a vacuum arc is generated between cathode 110 and anode 112, and plasma is generated. Constituent particles of this plasma includes vaporized material from cathode 110, and charged particles originating from the vaporized material and the reactant gas (ion, electron), together with molecules in pre-plasma state, and neutral particles such as atoms. Also, at the same time that plasma constituent particles are ejected, droplets with size from less than submicron to several hundred micron (0.01-1000 μm) are ejected. These droplets form a mixed state with plasma stream 126, and move inside the plasma advancing path as droplet mixture plasma.

At the plasma transport tube comprising plasma straightly advancing tube 103, first plasma advancing tube 104, second plasma advancing tube 105, and third plasma advancing tube 106, a magnetic field generating means for plasma transportation comprising magnetic field coils 117, 118, 119, 120 wound around each tube circumference is installed. The plasma transport efficiency can be improved by generating a magnetic field for plasma transportation throughout the entire three stages of said bent pathway.

Because the plasma advancing path is formed in a bent manner in three stages, magnetic field coil 121 generating a bending magnetic field and deflection magnetic field generating means 123 are installed at the tube connecting portion of first plasma advancing tube 104 and second plasma advancing tube 105, and they bend and guide the plasma stream by the bending magnetic field. Because a coil for bending magnetic field cannot be wound evenly at the connecting section of first plasma advancing tube 104 and second plasma advancing tube 105, heterogeneity of the magnetic field is produced in which the bending magnetic field becomes strong inward of the bending portion. To eliminate this uneven magnetic field, deflection magnetic field generating means 122, 124 are provided by first plasma advancing tube 104 and second plasma advancing tube 105.

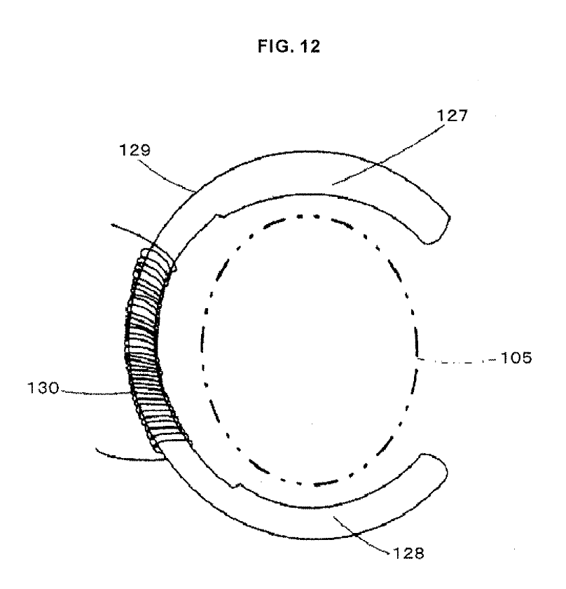

Deflection magnetic field generating means 122, 124 consist of deflection magnetic field generating coil 130 and movable yoke 129. FIG. 12 shows a state in which movable yoke 129 is arranged around the outer circumference of the second plasma advancing tube 105. Around movable yoke 129, deflection magnetic field generating coil 130 is wound, and it has a pair of magnetic poles 127, 128. A deflection magnetic field is generated between magnetic poles 127, 128, and applied toward the plasma in second plasma advancing tube 105.

Deflection magnetic field generating means 122, 124 include an adjustment mechanism, in which movable yoke 129 is adjusted by sliding along the tube axis direction, rotating along the circumferential direction, and swinging toward the tube axis direction.

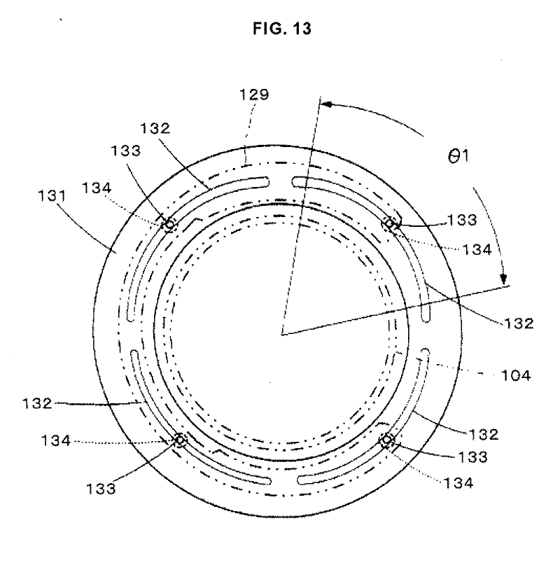

FIG. 13 shows a rotating adjustment mechanism of movable yoke 129 positioned around the outer circumference of first plasma advancing tube 104. The rotating adjustment mechanism comprises guide body 131 in which arc-like guiding grooves 132 that rotationally adjust movable yoke 129 in circumferential direction are installed in four places. Pins 133 set up at movable yoke 129 are inserted into guiding groove 132, and by sliding pins 133 in the tube circumferential direction, movable yoke 129 can be rotationally adjusted within angle adjustable range θ1 of less than or equal to 90 degrees. After the adjustment, the adjustment angle can be maintained by tightening pins 133 to guiding body 131.

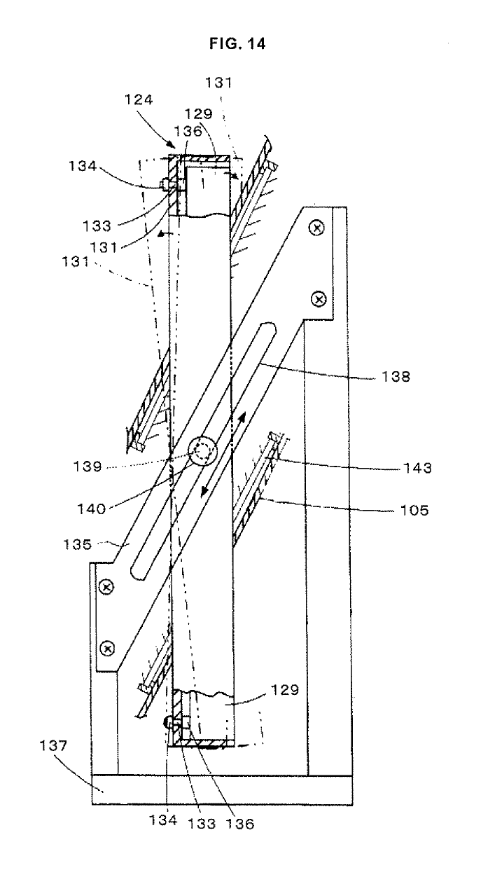

FIG. 14 shows an adjustment mechanism in which movable yoke 129 positioned circumferentially around the outer circumference of second plasma advancing tube 105 is adjusted by sliding toward the tube axis direction and by swinging toward the tube axis direction. Guiding body 131 is supported by slide member 135 in the state in which movable yoke 129 is fastened and held through spacer 136. Slide member 135 has straight slide groove 138 along the tube axis direction of second plasma advancing tube 105, and it is fastened to adjusting portion main body 137. Slide groove 138 is formed parallel to the inclination center line of second plasma advancing tube 105. The slide groove set up on first plasma advancing tube 104 is formed horizontally along the center line of first plasma advancing tube 104. Pin 139 set up on guiding body 131 is inserted into guiding groove 138, and by sliding pin 139 along the tube axis direction, movable yoke 129 of guiding body 131 can be slide-adjusted throughout almost the entire tube length of the second plasma advancing tube. After the adjustment, its adjusted position can be maintained by tightening pin 139 to slide member 135 with fastening nut 140, Also, guiding body 131 is supported on slide member 135 so that it is free to rotate around the axis of pin 139, in a state in which it fastens and holds movable yoke 129. Movable yoke 129 can be swing-adjusted (tilt angle adjustment) toward the tube axis direction by rotating around the axis of pin 139. After the adjustment, the adjustment tilt angle can be maintained by tightening pin 139 to slide member 135 with fastening nut 140. The adjustable tilt angle is 5° toward the first plasma advancing tube 104 side, and 30° toward the opposite side.

Because deflection magnetic field generating means 122, 124 make possible to adjust movable yoke 129 in a sliding manner in the tube axis direction, a rotating manner in the circumferential direction, and a swinging manner in the tube axis direction, a removal of the heterogeneity of the magnetic field for plasma transportation can be carried out by a fine adjustment by said deflection magnetic field through adjusting the position or the angle of movable yoke 129, and an optimum plasma advancing path comprising a geometrical arrangement of said bent pathway in three stages can be realized.

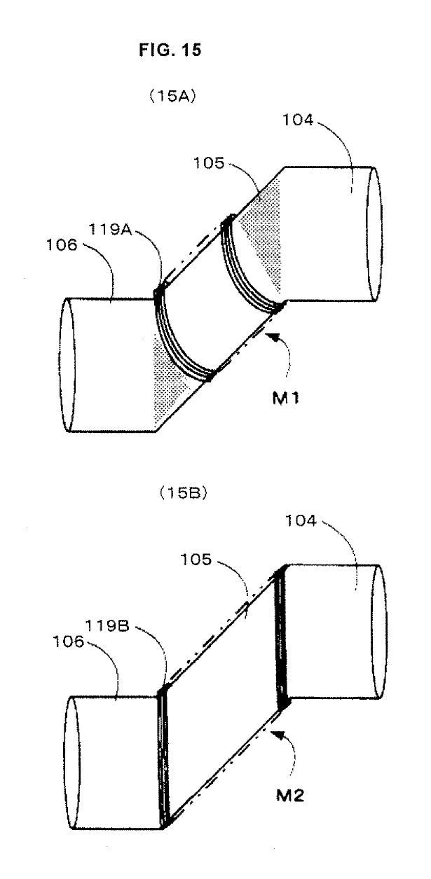

(15A) of FIG. 15 schematically shows state 119A in which a magnetic field coil for magnetic field generation for plasma transportation is wound in a circle M1-like configuration around an inclinedly arranged second plasma advancing tube 105 along its inclination axis. In this case, as shown by the hatched lines in the figure, gaps are formed near the connecting portions with other tubes (104 or 106) in which the coil is not wound, producing a heterogeneity in the magnetic field, and reducing the plasma transport efficiency.

In the present embodiment, magnetic field coil 119 wound around the outer tube circumference of second plasma advancing tube 105 comprises a magnetic field coil wound elliptically along the inclination axis outside its outer tube circumference. (15B) of FIG. 15 schematically shows state 119B in which magnetic field coil 119 for magnetic field generation for plasma transportation is wound in an oval M2-like configuration around an inclinedly arranged second plasma advancing tube 105 along its inclination axis. Because a gap such as the hatched areas in (15A) is prevented by setting up magnetic field coil 119 wound in an oval M2-like configuration on second plasma advancing tube 105, a plasma treatment using a high density and high purity plasma can be made possible by densely winding a magnetic field coil to the inclined surface of second plasma advancing tube 105 and improving the plasma transport efficiency without generating an uneven magnetic field.

To the plasma transport tube comprising plasma straightly advancing tube 103, first plasma advancing tube 104, second plasma advancing tube 105, and third plasma advancing tube 106, droplet collecting plates (baffles) 141, 142, 143, 144 are implanted on each respective tube inner wall surface. Structure of each collecting plate is explained in detail in the following.

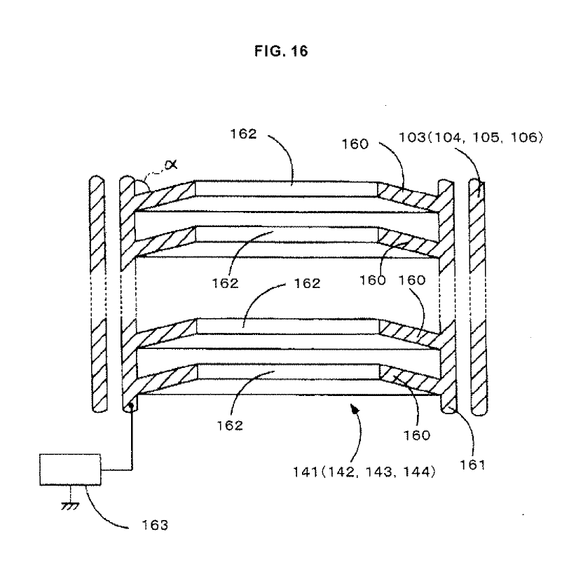

FIG. 16 is a partially enlarged cross-sectional view of inner circumferential tube 161 having droplet collecting plate 160. Inner circumferential tube 161 is built inside each plasma tube path (103-106), and a few droplet collecting plates 160 are implanted into its inner wall. Plasma stream circulation opening 162 is formed in the center of droplet collecting plate 160. The plasma flows in from the upper part of the figure, and passes through opening 162. Angle of inclination a of droplet collecting plate 160 is set within the range of 15-90°, but 30-60° is suitable according to experience, and it is set to α=60° in this embodiment. By this angle of inclination, the droplets separated from the plasma stream are reflected repeatedly by droplet collecting plates 160, and are adhered and collected reliably.

The droplet adhesion surface area of inner circumferential tube 161 is increased by multiple droplet collecting plates 160, and the scattered droplets can be adhered and collected in large quantities reliably. Because, in a plasma transport tube, the installation number of droplet collecting plates 160 is restricted by the limit of the tube length of inner circumferential tube 161, in order to increase the droplet removal area, it is preferable to do a rough surface processing on the surface of droplet collecting plates 160, and thus form rough surfaces having innumerable unevenness. That is to say, by roughening the surface of droplet collecting plates 160, the capture area of droplet collecting plates 160 is increased, and the collection efficiency can be improved. Also, the droplets collided in the recesses are adhered reliably in the recesses, and the droplet collection efficiency increases markedly. Linear pattern processing and pearskin processing can be used for the surface-roughening processing. For a linear pattern processing method, for example, a polishing treatment with an abrasive paper is used. For example, in a pearskin processing method, a blast treatment by alumina, shots, grids, glass beads and such is used. Especially, a microblast processing, in which particles of a few microns are accelerated and nozzle-sprayed, can apply a minute unevening processing on the small surfaces of droplet collecting plates 160.

The implanting area of droplet collecting plates 160 is preferably greater than or equal to 70% of the tube inner wall surface area. In the case of FIG. 8, the implanting area is made to be about 90% of the tube inner wall surface area. The scattering droplets can be adhered and collected reliably in a large quantity by the increase of the droplet adhesion surface area inside the tube for the plasma advancing path, and thus a high purity of the plasma flow can be realized.

Droplet collecting plates 160 are shielded electrically from the tube wall of each plasma advancing tube. To inner circumferential tube 161, inner circumferential tube bias power supply 163 is connected as bias voltage application means, and inner circumferential tube 161 can be set to positive electric potential, set to negative electric potential, or grounded to CND. In a case where the bias electric potential of inner circumferential tube 161 is a positive electric potential, it has an effect of pushing the positive ions of the plasma in the transportation direction, and in a case of a negative electric potential, it has an effect of pushing the electrons of the plasma in the transportation direction. The choice of either the positive or the negative is chosen toward the way in which the plasma transportation efficiency is not decreased, and it is decided from the state of the plasma. The electric potential strength is variable too, and it is usually chosen to set inner circumferential tube 161 to +15V from the standpoint of the transportation efficiency. By applying a bias voltage to each droplet collecting plate, its bias electric potential is adjusted, and attenuation of the plasma can be thus suppressed, thereby increasing the plasma transportation efficiency.

In second plasma advancing tube 105, one or more apertures 170 movable along the tube axis direction may be arranged. Said aperture 170 has a structure in which the installation position can be varied along the tube axis direction in second plasma advancing tube 105. A structure that can be moved both forward and backward is acceptable, and a structure that can be moved in only one direction is also acceptable. Because it is movable, the installation position of the aperture can be adjusted, and it also can be removed and washed. This aperture 170 has an opening of a predetermined area at the center, and the droplets are collided and captured on the peripheral wall surface of this opening, while the plasma passing through said opening advances. Said opening may be set up at the center, or it may be set up at an eccentric position. It can be designed in various manners. Therefore, if multiple apertures 170 are installed movably in second plasma advancing tube 105, the removal efficiency of the droplets increases, and the plasma purity can be improved. In the following, an aperture movable in one direction and using flat springs is shown.

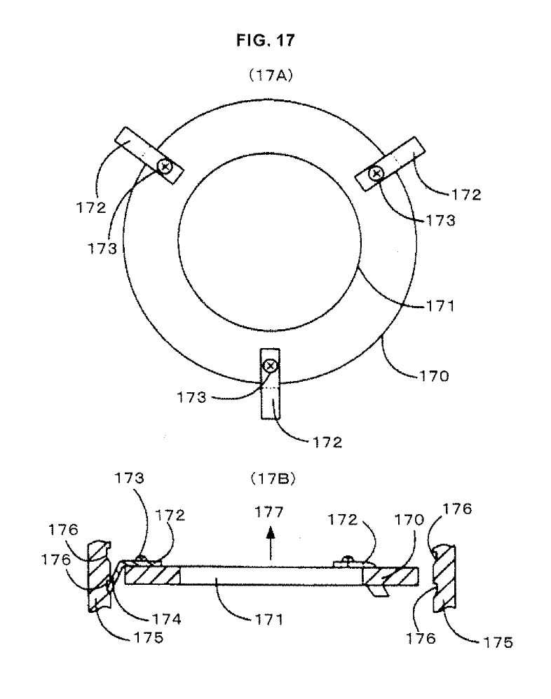

(17A) of FIG. 17 is a plane view of a movable aperture 170, and (17B) of said figure shows an installation state of aperture 170. Aperture 170 has a ring form having opening 171 of a predetermined area at the center. Here, the shape of said opening can be designed in a circular or an oval shape among others, depending on the placement configuration. At 3 locations of the surface of aperture 170, stoppers 172 comprising outward-protruding elastic pieces (for example, flat springs) are fastened by screws 173, but the fastening method can be adopted freely, such as welding. Protrusions 174 of the elastic pieces are bent downward. As shown in (17B) of FIG. 17, in the tube 175 inner wall of second plasma advancing tube 105, engagement recesses 176 for retaining aperture 170 are engraved beforehand in form of a circle. Engagement recesses 176 are set up in multiple numbers along the longitudinal direction of tube 175. When aperture 170 is inserted into tube 175 in the direction of arrow 177 while protrusions 174 of the elastic pieces are bent downward, stoppers 172 move along the tuber inner circumference surface while they push and bend. The direction of the plasma stream is the opposite direction of arrow 177. Furthermore, when aperture 170 is pushed toward the direction of arrow 177, protrusions 174 of stoppers 172 spread at engagement recess 176 by the elastic directional force, fit into engagement recess 176, and are locked. Stopper 172 cannot be moved in reverse in this locked state, and aperture 170 can be set in this locked position. When the set position is to be changed, the lock on stoppers 172 is removed upon pushing aperture 170 furthermore toward the direction of arrow 177, so that protrusions 174 can again be fitted in and locked on the next engagement recess 176.

Because aperture 170 has a structure in which it is movable to an arbitrary set position inside second plasma advancing tube 105, droplets can be collected by the decrease in the diameter of second plasma advancing tube 105 by aperture 170, and moreover, the set location can be changed appropriately so that the quantity of collection can be adjusted optimally, which contributes to an improvement in the droplet removal efficiency. The set number of apertures 170 is 1, 2 or more. In addition, opening 171 can be set up not only in the center of aperture 170, but it is possible to place it eccentrically in order to add a function to make the plasma flow inside the tube meander.

A ring shaped aperture may be arranged in a connecting section in the plasma advancing path comprising plasma straightly advancing tube 103, first plasma advancing tube 104, second plasma advancing tube 105, and third plasma advancing tube 106. In the same manner as aperture 170, by arranging this aperture for connecting section, the droplets included in the plasma stream can be collected in greater quantity, and the droplet removal efficiency can be improved, by reducing, making eccentric, or both reducing and making eccentric the tube diameter of the plasma advancing path.

In the plasma generating apparatuses of FIGS. 7 and 11, third plasma advancing tube 106 of the last stage is built with an even tube diameter, but it is preferable to increase further the density of the plasma stream passed through the bent pathway and exhausted from second plasma advancing tube 105, at third plasma advancing tube 106. Shown below is an embodiment in which a further high densification function is provided in third plasma advancing tube 106.

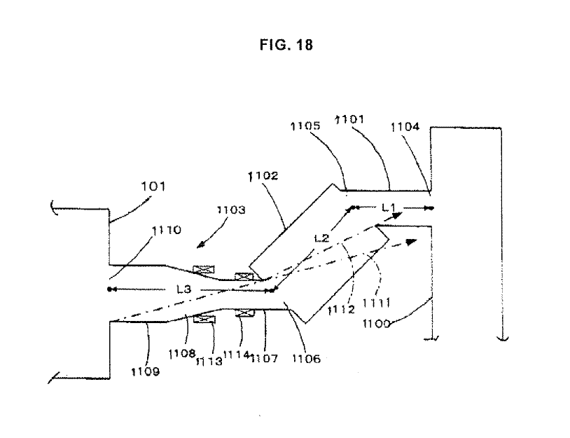

FIG. 18 shows the outlined scheme of a plasma processing apparatus of the fifth embodiment. The plasma processing apparatus of FIG. 18, in the same manner as FIG. 11, has a plasma generating apparatus comprising a plasma generating portion (not shown) for generating plasma to be supplied to plasma processing portion 101, and a plasma transport tube. The droplet removing portion set up in the plasma transport tube, in the same manner as FIG. 8, comprises plasma straightly advancing tube 1100 connected to the plasma generating portion, first plasma advancing tube 1101 connected to plasma straightly advancing tube 1100 in a bent manner at connecting port 1104, second plasma advancing tube 1102 inclinedly arranged and connected at the finishing end of first plasma advancing tube 1101 in a predetermined bending angle against its tube axis, and third plasma advancing tube 1103 connected in a bent manner at the finishing end of second plasma advancing tube 1102 so that plasma is exhausted from plasma outlet 1106. In addition, although not illustrated, droplet collecting plates and magnetic field coils for plasma transportation magnetic field formation are arranged in the plasma transport tube .

The plasma transport tube comprising plasma straightly advancing tube 1100, first plasma advancing tube 1101, second plasma advancing tube 1102, and third plasma advancing tube 1103 is formed in a bent manner in three stages, in the same manner as the plasma advancing paths of FIGS. 7 and 11. Third plasma advancing tube 1103 comprises rectifying tube 1107 connected at the finishing end of second plasma advancing tube 1102, frustoconical tube 1108 that becomes a deflection/oscillation tube connected to rectifying tube 1107, and outlet tube 1109. Frustoconical tube (deflection/oscillation tube) 1108 has its diameter increased toward the outlet tube 1109 side. Plasma outlet 1110 of outlet tube 1109 is connected to the plasma introduction port of plasma processing portion 101. Outlet tube 1109 has a constant diameter. In the plasma transport tube concerning the present embodiment, the respective plasma advancing lengths L1-L3 of first plasma advancing tube 1101, second plasma advancing tube 1102, and third plasma advancing tube 1103 are set to be same as each plasma advancing tube of FIG. 7. Also, at the position off the line of sight from plasma outlet 1110 of outlet tube 1109 to the plasma outlet 1105 side of first plasma advancing tube 1101, second plasma advancing tube 1102 is placed geometrically in the same manner as FIGS. 7 and 11. That is to say, when the angle of elevation from the tube cross section bottom end of the plasma outlet 1110 side of outlet tube 1109 to the tube cross section top end of the plasma outlet 1106 side of second plasma advancing tube 1102 is defined as θ₀ as shown by arrow 1112, the angle of elevation (θ) from the tube cross section top end of the plasma entrance port side of rectifying tube 1107 to the tube cross section bottom end of the plasma outlet 1105 side of first plasma advancing tube 1101 as shown by arrow 1111 satisfies θ≧θ₀ in the same manner as FIG. 7. By the same tube passage geometric placement as FIGS. 7 and 11, through avoiding the straightly advancing droplets led out from first plasma advancing tube 1101 directly intruding third plasma advancing tube 1103, they are prevented from being exhausted from plasma outlet 1110 of third plasma advancing tube 1103.

In the connecting section with third plasma advancing tube 1103 of the finishing end of second plasma advancing tube 1102 which has been inclinedly arranged, to prevent a decrease in the plasma progress efficiency to the third plasma advancing tube 1103 side through meandering and diffusion of the plasma flow, rectifying magnetic field coil 1114 is installed in rectifying tube 1107 connecting with second plasma advancing tube, so that a rectification magnetic field that rectifies while forcibly converging the plasma flow supplied from second plasma advancing tube 1102 to rectifying tube is generated in the tube. By this rectification magnetic field, the plasma flowing to second plasma advancing tube 1102 can be drawn in a converged manner at the third plasma advancing tube 1103 side, and a generation of plasma with high density and high purity becomes possible.

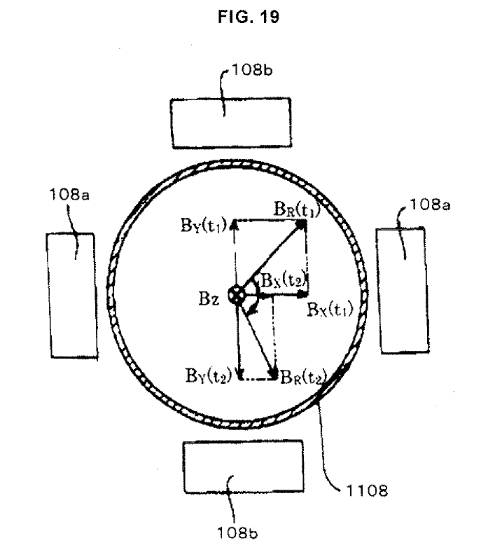

FIG. 19 is an explanatory diagram of a magnetic field for scanning formed inside frustoconical tube (deflection/oscillation tube) 1108 (shown in FIG. 18) concerning the fifth embodiment. As shown in FIGS. 18 and 19, to scan the plasma stream like a CRT display by oscillating left-right and up-down the plasma stream converged and rectified by the effect of the rectification magnetic field, magnetic field coil 1113 for scanning is provided near frustoconical tube (deflection/oscillation tube) 1108 connected to rectifying tube 1107. Magnetic field coil 1113 for scanning comprises a set of X-direction oscillating magnetic field generators 108a, 108a and a set of Y-direction oscillating magnetic field generators 108b, 108b.

The relations of X-direction oscillating magnetic field B_{X}(t) at time t by X-direction oscillating magnetic field generators 108a, 108a, Y-direction oscillating magnetic field B_{Y}(t) at time t by Y-direction oscillating magnetic field generators 108b, 108b, and scanning magnetic field B_{R}(t) at time t are shown. Scanning magnetic field B_{R}(t) is a synthetic magnetic field of X-direction oscillating magnetic field B_{X}(t) and Y-direction oscillating magnetic field B_{Y}(t). To explain in detail, while the plasma stream is oscillated left-right by the X-direction oscillating magnetic field, the plasma stream is scanned up-down by Y-direction oscillating magnetic field, and by repeating this, a large-area plasma exposure to plasma processing portion 1 is made possible. When the cross section area of the plasma stream is smaller than the cross section area of the object to be treated placed inside plasma treatment chamber 1, the plasma stream is scanned top-bottom and left-right, so that a plasma exposure is made possible on the entire surface of the object to be treated. A similar principle is used as, for example, when the electron beam of a CRT display oscillates left-right while moving up-down, and by repeating this movement, the entire surface of the display screen is made to emit light. In FIG. 19, magnetic field B_{R}(t₁) for scanning is synthesized from oscillating magnetic fields B_{X}(t₁) and B_{Y}(t₁) at time t=t₁, and while magnetic field B_{R}(t₁) for scanning oscillates left-right, magnetic field B_{R}(t₂) for scanning is formed at time t=t₂ by oscillating magnetic fields B_{X}(t₂) and B_{Y}(t₂), so that the plasma stream can be deflected and oscillated on almost the entire surface of the tube.

The present invention is not limited to the embodiments described above. Various modifications, design alterations, and others that do not involve a departure from the technical concept of the present invention are also included in the technical scope of the present invention.

### INDUSTRIAL APPLICABILITY

According to the present invention, a multiply divided anode wall type plasma generation apparatus can be provided that can improve the operation efficiency without decreasing the plasma generation efficiency by preventing an exfoliation of a large carbon flake. Also, according to a plasma processing apparatus concerning the present invention, an improvement of the operation efficiency is done by having installed a multiply divided anode wall type plasma generation apparatus, and at the same time, a high purification of the generated plasma can be realized by carrying out an elimination measure of neutral droplets and electrically charged droplets. Because of this, it becomes possible to form in the plasma a highly pure thin film whose defects and impurities on the surface of the solid material are markedly few, and to reform uniformly the surface characteristics of a solid without adding defects and impurities by irradiating the plasma, and a plasma processing apparatus can be provided for forming, for example, an abrasion- and corrosion-resistant reinforced film, a protective film, an optical thin film, and a transparent electroconductive film among others in high quality and precision.

1. In a plasma generation apparatus in which
a supply source of a plasma constituent is made to be a cathode,
a cylinder-shaped anode is installed at a front direction or a periphery of said cathode,
a vacuum arc discharge is done between said cathode and said anode under a vacuum environment,
and
plasma is generated from said cathode surface,
a plasma generation apparatus, characterized in that
a large number of recesses and protrusions is built on a cylinder inner wall that comprises said anode, so that when a part of said plasma ejected from said cathode to a direction of said anode adheres and deposits to said recesses and protrusions, said deposited matter detaches from said anode as a minute fragment.

2. The plasma generation apparatus of claim 1, wherein the longest length of a protruding portion of said recesses and protrusions is made shorter than the width of a gap between said cylinder inner wall and an outer circumference of said cathode.

3. The plasma generation apparatus of claim 1 or 2, wherein a large number of said recesses and protrusions is formed from any one of lattice-like, diagonally crossing, and island-like patterns.

4. The plasma generation apparatus of claim 1, wherein within said cylinder inner wall comprising said anode, the area near said cathode is made to be a formation area of said pattern for said recesses and protrusions, and an annular groove pattern, in which a multiple annular grooves are engraved in a front direction of said cathode, is formed on a remaining area of said cylinder inner wall.

5. The plasma generation apparatus of claim 1, wherein an annular recess position is formed at a periphery of said cathode, so that said minute piece detached from said anode is retained and collected in said annular recess position.

6. The plasma generation apparatus of claim 1, wherein a retention portion for said minute piece is installed beneath said cathode, and at the same time, an exposing portion that communicates with said retention portion is formed at a periphery of said cathode, so that said minute piece detached from said anode is retained and collected in said retention portion through said exposing portion.

7. A plasma processing apparatus, characterized in that it includes the plasma generation apparatus of claim 1, a plasma transport tube that transports said plasma generated by said plasma generating apparatus, and a plasma processing portion that processes an object to be treated by said plasma supplied from said plasma transport tube.

8. The plasma processing apparatus of claim 7, wherein
a starting end side insulator is interposed between a plasma outlet in a cylindrical body of said anode and said plasma transport tube,
a finishing end side insulator is interposed between said plasma transport tube and said plasma processing portion,
and
said plasma generating portion, said plasma transport tube, and said plasma processing portion are mutually separated electrically so that an electric influence from said plasma generating portion and said plasma processing portion on said plasma transport tube is blocked.

9. The plasma processing apparatus of claim 7 or 8, wherein said plasma transport tube comprises
a plasma straightly advancing tube connected to said plasma generating portion,
a first plasma advancing tube connected in a bent manner to said plasma straightly advancing tube,
a second plasma advancing tube diagonally arranged and connected at a finishing end of said first plasma advancing tube in a bent manner with predetermined bending angle with respect to a tube axis of said first plasma advancing tube,
a third plasma advancing tube connected in a bent manner to a finishing end of said second plasma advancing tube so that said plasma is exhausted from a plasma outlet,
and
total length L for said plasma to arrive from said target surface to said object to be treated is set to satisfy 900 mm≦L≦1350 mm.

10. The plasma processing apparatus of claim 9, wherein said second plasma advancing tube is placed geometrically at a position off a straight line of sight from a plasma outlet of said third plasma advancing tube to a plasma outlet side of said first plasma advancing tube.

11. The plasma processing apparatus of claim 9, wherein θ≧θ₀ is satisfied when
an angle of elevation from a tube cross section top end of the plasma entrance port side of said third plasma advancing tube to a tube cross section bottom end of the plasma outlet side of said first plasma advancing tube is defined as θ, and
an angle of elevation from a tube cross section bottom end of the plasma outlet side of said third plasma advancing tube to a tube cross section top end of the plasma outlet side of said second plasma advancing tube is defined as θ₀.

12. The plasma processing apparatus of claim 9, wherein
a magnetic field generating means for plasma transportation that generates a magnetic field for plasma transportation is set up in each of said plasma straightly advancing tube, said first plasma advancing tube, said second plasma advancing tube, and said third plasma advancing tube,
a deflection magnetic field generating means for deflecting said magnetic field for plasma transportation is attached in said first plasma advancing tube and/or said second plasma advancing tube,
and
a plasma stream is deflected toward a tube center side by a deflection magnetic field generated by said deflection magnetic field generating means.
